(19) United States
(12) Patent Application Publication
(10) Pub. No.: US 2017/0263693 A1
(43) Pub. Date: Sep. 14, 2017

(54) SEMICONDUCTOR DEVICE

(71) Applicant: Renesas Electronics Corporation, Tokyo (JP)

(72) Inventor: Ryuichi OIKAWA, Tokyo (JP)

(21) Appl. No.: 15/378,535

(22) Filed: Dec. 14, 2016

(30) Foreign Application Priority Data
Mar. 8, 2016 (JP) 2016-044354

(51) Int. Cl. H01L 49/02; H01L 25/065; H01L 23/522

(52) U.S. Cl. CPC H01L 28/60; H01L 23/5223; H01L 25/0657

(57) ABSTRACT

A semiconductor device includes a capacitive element that has frequency dependency that a capacitance value obtained when a second frequency signal that is higher in frequency than a first frequency signal has been applied becomes smaller than a capacitance value obtained when the first frequency signal has been applied and thereby improvement of performance of the semiconductor device is promoted.

### CROSS-REFERENCE TO RELATED APPLICATIONS

The disclosure of Japanese Patent Application No. 2016-044354 filed on Mar. 8, 2016 including the specification, drawings and abstract is incorporated herein by reference in its entirety.

### BACKGROUND

The present invention relates to a semiconductor device, and, for example, relates to a technology that is effectively applied to the semiconductor device that makes high speed communication possible.

In Japanese Unexamined Patent Application Publication No. 2014-204057, there is described a technology for installing a through-via that functions as a capacitive element at a position that is separated from an end of an I/O (input/output) terminal by ¼ (=λ/4) of a signal wavelength (λ) in a signal transmission line on a wiring board to be coupled to the I/O terminal.

In Japanese Unexamined Patent Application Publication No. 2014-107415, there is described a technology that relates to a capacitor element that includes a capacitance value between an N type well formed in a semiconductor substrate and a first electrode formed over the semiconductor substrate and a capacitance value between the first electrode and a second electrode formed over the first electrode.

### SUMMARY

For example, on a transmission line between semiconductor devices that each includes a semiconductor chip having an input/output unit that copes with high speed transmission, a reflected signal that would generate due to a parasitic capacitance that is present in the input/output unit is liable to appear as a main cause for reducing the performance of the semiconductor device. That is, since this reflected signal becomes noise on the transmission line, it is requested to remove the reflected signal.

In regard to this point, there is a technology of intentionally installing a capacitive element that generates an inversion signal used for inverse cancellation of the reflected signal on a wiring board that configures part of the semiconductor device for cancellation of the reflected signal. However, in this technology, it is requested to increase the number of the capacitive elements with increasing the frequency of the signal used. In particular, recently, a space for loading the capacitive elements on the wiring board has been reduced as speeding-up of a signal speed is requested. Accordingly, it is requested to devise so as to allow noise reduction on the transmission line without increasing the number of the capacitive elements used for generating the inversion signal for inverse cancellation of the reflected signal while coping with an increase in frequency band with speeding-up of the signal speed.

Other subjects and novel features of the present invention will become apparent from the description of the present specification and the appended drawings.

According to one embodiment of the present invention, there is provided a semiconductor device that includes a capacitive element that has frequency dependency that a capacitance value obtained when a second frequency signal that is higher in frequency than a first frequency signal has been applied becomes smaller than a capacitance value obtained when the first frequency signal has been applied.

According to one embodiment, it is possible to promote improvement of performance of the semiconductor device.

### BRIEF DESCRIPTION OF THE DRAWINGS

FIG. 1 is a schematic diagram illustrating one example of a configuration that an output unit formed in a semiconductor chip that has been loaded on one semiconductor device has been coupled with an output unit formed in a semiconductor chip that has been loaded on the other semiconductor device via a transmission line.

FIG. 2 is a schematic diagram illustrating one example of a configuration that copes with a situation that a frequency band of a signal used is to be increased with the technology illustrated in FIG. 1 being defined as a basic configuration.

FIG. 3 is a schematic diagram illustrating one example of a state where a semiconductor device according to a first related technology has been loaded on a mounting board (a mother board).

FIG. 4 is a schematic diagram illustrating one example of a state where a semiconductor device according to a second related technology has been loaded on the mounting board (the mother board).

FIG. 5 is a schematic diagram illustrating one example of one mechanism adapted to realize a capacitive element having frequency dependency that is a basic idea according to a first embodiment.

FIG. 6 is a schematic diagram illustrating one example of another mechanism adapted to realize the capacitive element having the frequency dependency that is the basic idea according to the first embodiment.

FIG. 7 is a plan view illustrating one example of a schematic configuration of the capacitive element according to the first embodiment.

FIG. 8 is a sectional diagram taken along the A-A line in FIG. 7.

FIG. 9 is a schematic diagram illustrating one example of a case where a low frequency signal has been applied to the capacitive element according to the first embodiment.

FIG. 10 is a schematic diagram illustrating one example of a case where a high frequency signal has been applied to the capacitive element according to the first embodiment.

FIG. 11 is a graph illustrating one example of a result of simulation performed on the frequency dependency of the capacitive element according to the first embodiment.

FIG. 12 is a diagram schematically illustrating one example of a configuration of coupling between a first semiconductor device and a second semiconductor device loaded on a mounting board.

FIG. 13 is a diagram schematically illustrating one example of a configuration of the first semiconductor device loaded on the mounting board.

FIG. 14 is a plan view illustrating one example of a planar layout configuration of the capacitive element according to the first embodiment.

FIG. 15 is a sectional diagram taken along the A-A line in FIG. 14.

FIG. 16 is a sectional diagram illustrating one example of a first altered example and corresponding to the section taken along the A-A line in FIG. 14.

FIG. 17 is a sectional diagram illustrating one example of a second altered example and corresponding to the section taken along the A-A line in FIG. 14.

FIG. 18 is a sectional diagram taken along the B-B line in FIG. 14.

FIG. 19 is a plan view illustrating one example of a schematic configuration of a capacitive element according to a second embodiment.

FIG. 20 is a sectional diagram taken along the A-A line in FIG. 19.

FIG. 21 is a schematic diagram illustrating one example of a part (a dotted part) of a second upper electrode that functions as an effective electrode when the low frequency signal has been applied to a first upper electrode.

FIG. 22 is a schematic diagram illustrating one example of the part (the dotted part) of the second upper electrode that functions as the effective electrode when the high frequency signal has been applied to the first upper electrode.

FIG. 23 is a graph illustrating one example of a result of simulation performed on the frequency dependency of the capacitive element according to the second embodiment.

FIG. 24 is a schematic diagram illustrating one example of a planar layout configuration of a capacitive element according an altered example of the second embodiment.

FIG. 25 is a schematic diagram illustrating one example of a specific planar layout configuration of the capacitive element according to the second embodiment.

FIG. 26 is a diagram illustrating one example of a schematic configuration of a semiconductor device according to a third embodiment.

FIG. 27 is a plan view illustrating one example of a planar layout configuration of one pair of capacitive elements according to the third embodiment.

FIG. 28 is a sectional diagram taken along the A-A line in FIG. 27.

FIG. 29 is a sectional diagram taken along the B-B line in FIG. 27.

FIG. 30 is a diagram illustrating one example of a schematic configuration of a semiconductor device according to an altered example of the third embodiment.

FIG. 31 is an enlarged diagram illustrating one example of a planar layout configuration of an impedance discontinuity area.

FIG. 32 is a graph illustrating one example of a relation between a frequency and a return loss (a reflection loss) in a related technology.

FIG. 33 is a graph illustrating one example of a relation between the frequency and the return loss (the reflection loss) in an altered example.

### DETAILED DESCRIPTION

Although, in the following embodiments, description will be made by dividing into a plurality of sections or embodiments when division is requested for the convenience sake, these are not unrelated to each other or one another and these are related to each other or one another such that one covers some or all of altered examples, detailed explanation, supplemental explanation and so forth of the other(s) except as clearly stated in particular.

In addition, in the following embodiments, in a case where the number of constitutional elements and so forth (the number of units, a numerical value, an amount/a quantity, a range and so forth are included) is referred to, it is not limited to the specific number and may be at least and/or not more than the specific number except as clearly stated in particular and except as definitely limited to the specific number in principle.

Further, in the following embodiments, it goes without saying that the constitutional elements (element steps and so forth are also included) thereof are not necessarily essential except as clearly stated in particular and except as clearly thought to be essential in principle.

Likewise, in the following embodiments, when the shapes of the constitutional elements and so forth, a positional relationship among them and so forth are referred to, the ones that are substantially approximate or similar to the shapes and so forth shall be included except as clearly stated in particular and except as clearly thought that they are not approximate or similar thereto in principle. The same is true of the above-mentioned numerical value and the range.

In addition, in all of the drawings illustrated in order to describe the embodiments, the same numerals are assigned to the same members in principle and repetitive description thereof is omitted. Incidentally, there are cases where hatching is added even in a plan view for easy illustration of the drawings.

### First Embodiment

### <Examination of Improvement>

For example, an input/output unit (an I/O unit) adapted to interface with an external circuit is formed on a semiconductor chip that an integrated circuit is formed, and the input/output unit is electrically coupled with a transmission line that is coupled with a semiconductor device. In this case, a reflected signal is generated from a signal that is transmitted through the transmission line caused by a parasitic capacitance that is present in the input/output unit and the reflected signal becomes noise on the transmission line.

From the above, there is known a technology for reducing the noise on the transmission line caused by the reflected wave (signal) by generating an inversion signal that is out of phase with the above-mentioned reflected signal by about 180 degrees and cancelling the reflected signal and the inversion signal each other.

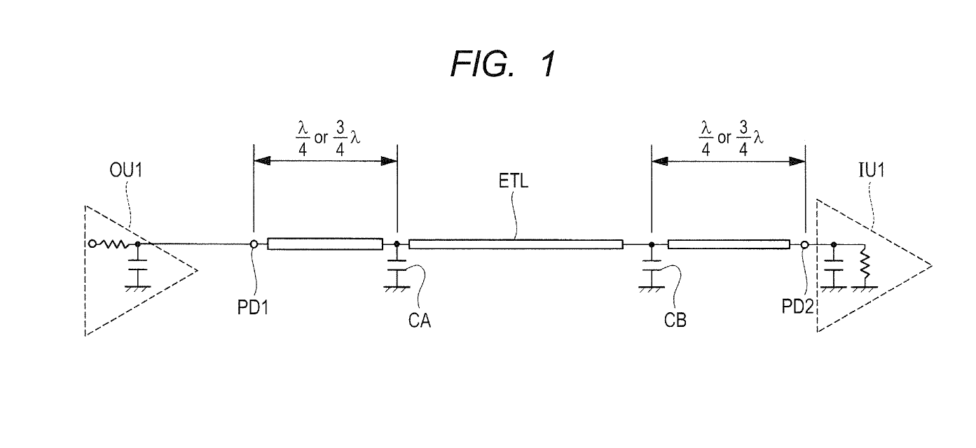

In the following, this technology will be described with reference to the drawings. FIG. 1 is a schematic diagram illustrating one example of a configuration that an output unit that is formed on a semiconductor chip loaded on one semiconductor device has been coupled with an input unit that is formed on a semiconductor chip loaded on the other semiconductor device via a transmission line. In FIG. 1, an output unit OU1 that is formed on one semiconductor chip and an input unit IU1 that is formed on the other semiconductor chip are electrically coupled together via a transmission line ETL. Accordingly, it is possible to transmit a signal from the output unit OU1 of one semiconductor chip to the input unit IU1 of the other semiconductor chip via the transmission line ETL.

In this case, since the parasitic capacitance is present in each of the output unit OU1 and the input unit IU1, the reflected signal is generated from the signal due to impedance mismatching which would occur between each of the output unit OU1 and the input unit IU1 and the transmission line ETL due to presence of the parasitic capacitance. Then, the reflected signal so generated is repetitively reflected by the output unit OU1 and the input unit IU1 and is consequently present on the transmission line ETL as the noise. For this reason, it is requested to remove the reflected signal in order to reduce the noise on the transmission line ETL. Accordingly, in the technology illustrated in FIG. 1, for example, when a wavelength of the signal is designated by λ, a capacitive element CA is arranged at a position that is separated from a pad PD1 of one semiconductor chip by about λ/4 or about 3λ/4. Likewise, in the technology illustrated in FIG. 1, also a capacitive element CB is arranged at a position that is separated from a pad PD2 of the other semiconductor chip by about λ/4 or about 3λ/4. Thereby, in the technology illustrated in FIG. 1, it is possible to generate the inversion signal used for cancellation of the reflected signal generated by signal reflection in the output unit OU1 and the input unit IU1.

This is because, for example, since the distance between the pad PD1 and the capacitive element CA is about λ/4 or about 3λ/4, when considering a round trip distance between the pad PD1 and the capacitive element CA, it is possible to set a phase difference between the reflected signal that is reflected by the pad PD1 and the inversion signal that is reflected by the capacitive element CA to about 180 degrees. Likewise, since it is also possible to reflect the reflected signal by appropriately setting a capacitance value of the capacitive element CB and, for example, the distance between the pad PD2 and the capacitive element CB is about λ/4 or about 3λ/4, when considering the round trip distance between the pad PD2 and the capacitive element CB, it is possible to set a phase difference between the reflected signal that is reflected by the pad PD2 and the inversion signal that is reflected by the capacitive element CB to about 180 degrees. Consequently, it is possible to cancel the reflected signal and the inversion signal each other on the transmission line ETL and thereby it is possible to reduce the noise which would generate on the transmission line ETL due to presence of the reflected signal.

Here, it is supposed that “the reflected signal” that is described in this specification means a signal that has been reflected by, for example, the pad (PD1, PD2) illustrated in FIG. 1 and “the inversion signal” that is described in this specification means a signal that has been reflected by the capacitive element (CA, CB).

Incidentally, in order to set the phase difference between the reflected signal and the inversion signal to about 180 degrees, it is also possible to realize 180-degree phase difference by arranging the capacitive element CA (CB) at a position that is separated from the pad by about λ/4+λ/2×n (n is two or more natural numbers) not limited to about λ/4 or about 3λ/4. However it is desirable to arrange the capacitive element CA (CB) at the position that is separated from the pad by about λ/4 or about 3λ/4. This is because, for example, focusing on the capacitive element CA, when the capacitive element CA is arranged at the position that is separated from the pad PD1 by about λ/4+λ/2×n (n is two or more natural numbers), the distance between the pad PD1 and the capacitive element CA is increased and it means that a parasitic inductance is increased. That is, that the parasitic inductance is increased means that the Q value is increased sharply and a half-value width becomes narrow and this means that a frequency band of the signal that is reflected by the capacitive element CA becomes narrow. That is, in the first embodiment, a digital signal is supposed as the signal to be transmitted through the transmission line ETL and the digital signal is configured by a rectangular signal that includes many frequency components. Therefore, that the frequency band of the signal that is reflected by the capacitive element CA becomes narrow means that only some frequency components contained in the rectangular signal are reflected and thereby the waveform of the inversion signal is deformed from the rectangular shape. In this case, mutual cancellation of the reflected signal and the inversion signal is not sufficiently performed and it becomes difficult to sufficiently ensure flatness of cancellation. Accordingly, as the arrangement position of the capacitive element CA, it is desirable to arrange the capacitive element CA at the position that is separated from the pad PD1 by about λ/4 or about λ¾ so as to reduce the parasitic inductance.

According to the technology so configured and illustrated in FIG. 1, since it is not requested to load a circuit for cancellation of the parasitic capacitance that the input/output unit has on the semiconductor chip, it is possible to reduce the noise on the transmission line ETL without obstructing miniaturization of the semiconductor chip.

However, in the technology illustrated in FIG. 1, it is requested to make a device when the frequency band of the signal has been increased. For example, when the frequency of the signal has been doubled, the phase difference between the inversion signal reflected by the capacitive element CA illustrated in FIG. 1 and the reflected signal reflected by the pad PD1 illustrated in FIG. 1 is not about 180 degrees (anti-phase) and is increased to about 360 degrees (in-phase). This means that the reflected signal and the inversion signal are not cancelled each other and superimposition (amplification) of the reflected signal and the inversion signal occurs and such a side effect that the intensity of the reflected signal is rather increased occurs.

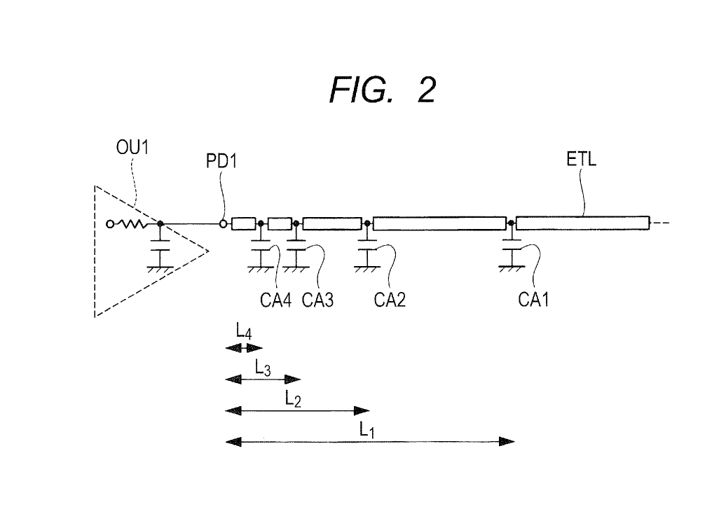

Accordingly, in the technology illustrated in FIG. 1, it is requested to adopt a configuration illustrated in FIG. 2 in order to increase the frequency band of the signal. FIG. 2 is a schematic diagram illustrating one example of a configuration that copes with a case where the frequency band of the signal is to be increased with the technology illustrated in FIG. 1 being used as the basic configuration. In FIG. 2, a capacitive element CA1 that copes with cancellation of the reflected signal in the signal of the wavelength λ is arranged at a position that is separated from the pad PD1 by L₁ (=λ/4). In this case, the capacitive element CA1 contributes not to cancellation but to amplification of the reflected signal for the signal whose frequency has been doubled. Accordingly, it is requested to arrange a capacitive element CA2 that copes with cancellation of the reflected signal in the signal whose frequency has been doubled at a position that is separated from the pad PD1 by L₂ (=½×L₁). Likewise, when a signal whose frequency has been quadrupled is to be used, it is requested to arrange a capacitive element CA3 that copes with cancellation of the reflected signal in this signal at a position that is separated from the pad PD1 by L₃ (=½×L₂). Further, when a signal whose frequency has been octupled is to be used, it is requested to arrange a capacitive element CA4 that copes with cancellation of the reflected signal in this signal at a position that is separated from the pad PD1 by L₄ (=½×L₃). In the technology illustrated in FIG. 1, it is requested to increase the number of the capacitive elements one by one every time the frequency band of the signal is increased so as to cover the signal whose frequency has been doubled in this way. Accordingly, in the technology illustrated in FIG. 1, the positions and the number of the capacitive elements to be arranged on the transmission line are determined in conformity to the frequency band of the signal used. This means that it is requested to additionally arrange each capacitive element at each position that is closer to the pad PD1 (the output unit OU1) than others every time the frequency of the signal used is doubled as illustrated in FIG. 2 and therefore it is expected that it will become difficult eventually to additionally install the capacitive elements with increasing the frequency band of the signal used.

Description will be made on this point by using a related technology. Incidentally, the “related technology” described in this specification is a technology that has a subject that the inventors and others have newly found and is not well-known related art, that is, it is a technology that has been described with the intention of introducing an underlying technology (an unknown technology) of a novel technical idea.

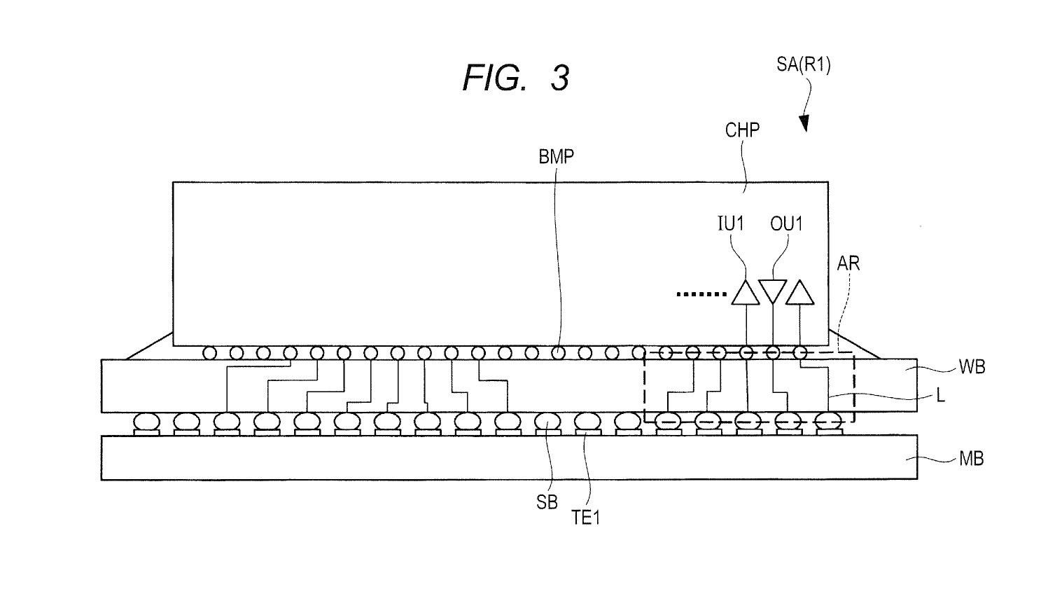

FIG. 3 is a schematic diagram illustrating one example of a state where a semiconductor device according to a first related technology has been loaded on amounting board (a mother board). In FIG. 3, a semiconductor device SA(R1) is loaded on a mounting board MB. Specifically, a wiring board WB that configures part of the semiconductor device SA(R1) is arranged on the mounting board MB and a plurality of solder balls SB that are formed on a back face of the wiring board WB are coupled with terminals TE1 that are formed on a front face of the mounting board MB. Then, wiring lines L that are coupled with the solder balls SB are formed in the wiring board WB. In addition, a semiconductor chip CHP that configures part of the semiconductor device SA(R1) is loaded on the front face of the wiring board WB and bump electrodes BMP that are formed on a back face of the semiconductor chip CHP are electrically coupled with the wiring lines L that are formed in the wiring board WB. Then, the input units IU1 and the output units OU1 illustrated in FIG. 3 are formed in the semiconductor chip CHP together with an integrated circuit (not illustrated) that configures a core circuit. Each of the input units IU1 and the output units OU1 is electrically coupled with each of the bump electrodes BMP. In the semiconductor device SA(R1) so configured, the capacitive elements CA1 to CA4 that are illustrated in FIG. 2 are to be arranged on the wiring lines L that are located in a chain-lined area AR of the wiring board WB in FIG. 3. However, in the semiconductor device SA(R1) in the first related technology, since there is a limit on the space in the wiring board WB, it becomes difficult to additionally install the capacitive elements in the wiring board WB with increasing the frequency band of the signal used.

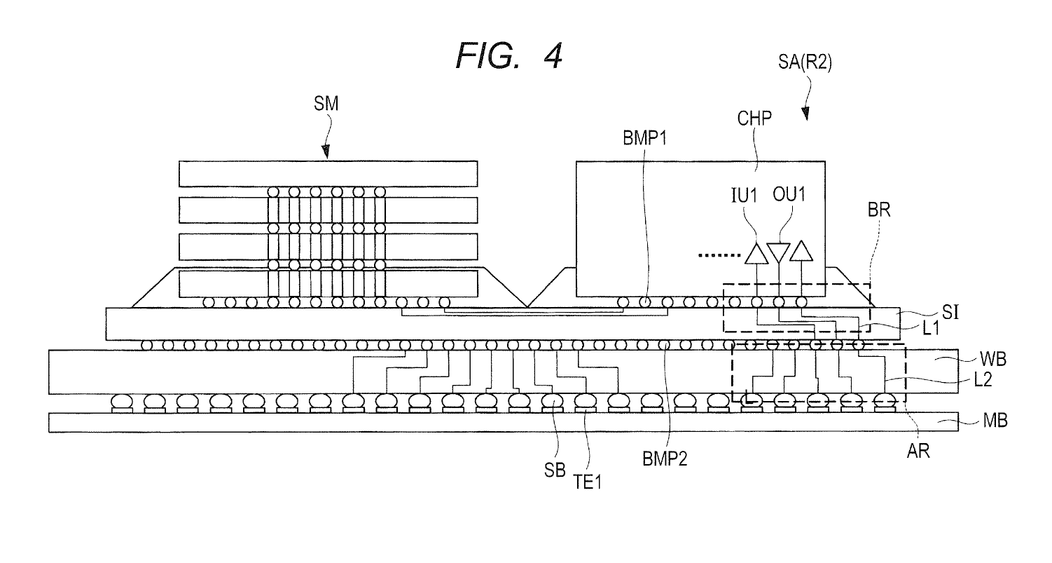

Accordingly, as one solving method, it is conceived to adopt a structure of a semiconductor device in a second related technology illustrated in FIG. 4. FIG. 4 is a schematic diagram illustrating one example of a state where the semiconductor device in the second related technology has been loaded on the mounting board (the mother board). In FIG. 4, a semiconductor device SA(R2) is loaded on the mounting board MB. The semiconductor device SA(R2) includes the wiring board WB that has wiring lines L2 therein, a silicon interposer SI that is a semiconductor layer (a semiconductor board) that is loaded on the wiring board WB and has wiring lines L1 therein, the semiconductor chip CHP and a stacked memory SM loaded on the silicon interposer SI and so forth. In the semiconductor device SA(R2) so configured, the silicon interposer SI adapted to electrically couple together, for example, the semiconductor chip CHP with a logic circuit (a control circuit) being formed and the stacked memory SM that includes a memory circuit is installed. Accordingly, in the semiconductor device SA(R2) in the second related technology, it is possible to use not only the wiring lines L2 that are formed in the wiring board WB but also the wiring lines L1 that are formed in the silicon interposer SI for installation of the capacitive elements. That is, since according to the semiconductor device SA(R2) in the second related technology, it is possible to use a larger number of wiring layers than the number of the wiring layers of the semiconductor device in the first related technology for installation of the capacitive elements, it is possible to install a larger number of the capacitive elements, coping with a certain increase in frequency band of the signal used.

However, it is still requested to increase the number of the capacitive elements one by one every time the frequency band is increased so as to cover the signal whose frequency has been doubled, it may not be said that the method according to the second related technology is a drastic solving method and it is apparent that it will become difficult eventually to additionally install the capacitive elements.

Considering the above-mentioned examination, it is desirable to devise so as to reduce the noise on the transmission line ETL without increasing the number of the capacitive elements for generating the inversion signals used for inverse cancellation of the reflected signals while coping with an increase in frequency band with speeding-up of the signal speed. Specifically, when the frequency band is increased so as to cover the signal whose frequency is doubled, the phase difference between the inversion signal reflected by the capacitive element and the reflected signal reflected by the pad PD1 is not about 180 degrees (anti-phase) and is increased to about 360 degrees (in-phase) in the signal whose frequency is doubled. Consequently, when the frequency band is increased so as to cover the signal whose frequency is doubled, the reflected signal and the inversion signal are not cancelled each other and superimposition of the reflected signal and the inversion signal occurs and such a side effect that the intensity of the reflected signal is rather increased occurs. Accordingly, it is conceived that elimination of this side effect itself leads to provision of the drastic solving method for reducing the noise on the transmission line ETL without increasing the number of the capacitive elements to be arranged.

### Basic Idea of First Embodiment

In the following, a technical idea of the first embodiment that would become the above-mentioned drastic solving method will be described. First, the basic idea of the first embodiment will be described.

The basic idea of the first embodiment lies in the point that a capacitive element that has frequency dependency that a capacitance value obtained when a second frequency signal that is higher in frequency than a first frequency signal has been applied becomes smaller than a capacitance value obtained when the first frequency signal has been applied is used as, for example, the capacitive element CA to be arranged on the transmission line illustrated in FIG. 1. Thereby, it is possible to generate the inversion signal used for cancellation of the reflected signal of the first frequency signal by this capacitive element, for example, by appropriately setting the capacitance value obtained when the first frequency signal has been applied. Consequently, the reflected signal of the first frequency signal and the inversion signal reflected by the capacitive element are cancelled each other and it is possible to reduce the noise on the transmission line ETL caused by the reflected signal of the first frequency signal.

On the other hand, in the capacitive element according to the first embodiment, the capacitance value is reduced for the second frequency signal that is higher than the first frequency signal in frequency. This means that the inversion signal is not generated from the capacitive element for the reflected signal of the second frequency signal. That is, while the capacitive element having the above-mentioned frequency dependency has a function of generating the inversion signal caused by a large capacitance value for the reflected signal of the first frequency signal, the capacitance value is reduced for the reflected signal of the second frequency signal and, as a result, the inversion signal is not generated for the reflected signal of the second frequency signal. That is, it may be said that the capacitive element having the above-mentioned frequency dependency has a function of not generating the inversion signal for the second frequency signal. Thereby, since in the capacitive element according to the first embodiment, the inversion signal is not generated for the second frequency signal, it is possible to suppress such a side effect that the inversion signal and the reflected signal are mutually superimposed (amplified).

Specifically, for example, supposing a case where the second frequency is two times as large as the first frequency signal in frequency, in a general capacitive element that the capacitance value has no frequency dependency, the inversion signal is generated also for the second frequency signal, and in addition, the phase difference between the reflected signal and the inversion signal is not about 180 degrees and is increased to about 360 degrees. From this fact, when the general capacitive element is used, the side effect that the reflected signal and the inversion signal are amplified occurs instead of mutual cancellation of the reflected signal and the inversion signal.

In contrast, according to the capacitive element that has the above-mentioned frequency dependency in the first embodiment, while it is possible to cancel the reflected signal and the inversion signal each other for the first frequency signal, the capacitance value is reduced and, as a result, the inversion signal is not generated for the second frequency signal. This means that according to the capacitive element of the first embodiment, since the inversion signal is not generated for the second frequency signal, it is possible to suppress the side effect that is called amplification of the reflected signal and the inversion signal. Consequently, it is possible to eliminate the side effect itself by using the capacitive element according to the first embodiment. Therefore, according to the basic idea of the first embodiment, it is possible to eliminate the side effect itself and, as a result, it is possible to provide the drastic solving method for reducing the noise on the transmission line without increasing the number of the capacitive elements to be arranged.

### <Matters for Examination in Realizing the Basic Idea>

It is understood that the basic idea of the first embodiment is useful in the point that, according to the basic idea, it is possible to provide the drastic solving method for reducing the noise on the transmission line ETL without increasing the number of the capacitive elements to be arranged as mentioned above. Thus, next, matters for examination in realizing the basic idea of the first embodiment will be described.

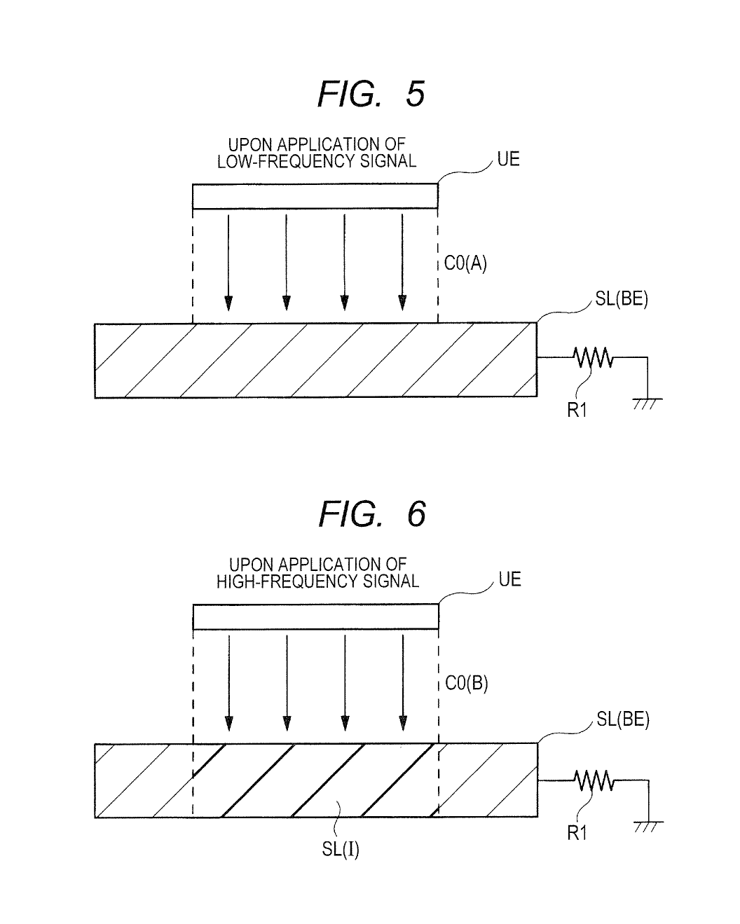

FIG. 5 and FIG. 6 each is a schematic diagram illustrating one example of a mechanism for realizing the capacitive element having the frequency dependency that is the basic idea of the first embodiment. First, in FIG. 5, for example, a lower electrode BE of the capacitive element is configured by a semiconductor layer SL (a semiconductor substrate, a substrate layer) and an upper electrode UE of the capacitive element is configured by a conductor film that has been arranged above the semiconductor layer SL.

In this case, for example, the lower electrode BE of the capacitive element is electrically coupled to ground via a parasitic resistor R1 and a low frequency signal is applied to the upper electrode UE. In this case, as illustrated in FIG. 5, since the low frequency signal that changes with time is applied to the upper electrode UE of the capacitive element, carriers (charges) contained in the semiconductor layer SL vibrate due to presence of the low frequency signal. That is, when the signal that is applied to the upper electrode UE of the capacitive element is the low frequency signal, the carriers contained in the semiconductor layer SL vibrate following the low frequency signal. This means that the semiconductor layer SL functions as a conductor. Accordingly, when the low frequency signal has been applied to the upper electrode UE as illustrated in FIG. 5, the semiconductor layer SL acts as the conductor and therefore the semiconductor layer SL functions as the lower electrode BE. Consequently, for example, a capacitive element having a capacitance value CO(A) is formed by the upper electrode UE and the semiconductor layer SL (the lower electrode BE) in FIG. 5.

On the other hand, for example, a case where a high frequency signal has been applied to the upper electrode UE of the capacitive element is considered. Also, in this case, since the high frequency signal that changes with time is applied to the upper electrode UE of the capacitive element as illustrated in FIG. 6, the carriers (the charges) contained in the semiconductor layer SL try to vibrate due to the presence of the high frequency signal. However, since the signal that is applied to the upper electrode UE of the capacitive element is the high frequency signal, the carriers contained in the semiconductor layer SL fail to follow the high frequency signal and hence do not vibrate. This means that the semiconductor layer SL functions as an insulator (a dielectric). Accordingly, when the high frequency signal has been applied to the upper electrode UE as illustrated in FIG. 6, a semiconductor layer SL(I) that overlaps the upper electrode UE planarly acts as an insulator. However, as illustrated in FIG. 6, since a part of the semiconductor layer SL that does not overlap the upper electrode UE planarly is hardly influenced by the high frequency signal, the semiconductor layer SL still functions as the conductor and the above-mentioned part of the semiconductor layer SL functions as the lower electrode BE. Consequently, as illustrated in FIG. 6, when the high frequency signal has been applied to the upper electrode UE, a capacitive element having, for example, a capacitance value CO(B) that is smaller than the capacitance value CO(A) is formed by the upper electrode UE and the part of the semiconductor layer SL that does not planarly overlap the upper electrode UE.

It is possible to realize the capacitive element having the frequency dependency that is the basic idea of the first embodiment by the mechanisms illustrated in FIG. 5 and FIG. 6. However, since according to the examination done by the inventors and others of the present invention, it has been found that further examination is requested in designing the actual capacitive element, in the following, the matters for examination will be described.

For example, when the low frequency signal has been applied to the upper electrode UE, it is requested to induce reflection of the low frequency signal by the capacitive element of the capacitance value CO(A) illustrated in FIG. 5 and it is requested to increase the capacitance value CO(A) of the capacitive element to some extent in order to induce reflection of the low frequency signal. Therefore, in the capacitive element illustrated in FIG. 5, it is requested to increase the planar size of the upper electrode UE in order to ensure the capacitance value CO(A). Then, to apply the low frequency signal to the upper electrode UE itself means that it is requested to electrically couple the upper electrode UE with a signal line through which the low frequency signal is transmitted. However, in the present situation of the semiconductor device, the signal lines are arranged highly densely in consideration of miniaturization of the semiconductor device and there is no space for installation of the upper electrode UE of a large area to be coupled with the signal line. Accordingly, considering restrictions imposed on actual design, it becomes difficult to realize the capacitive element of the configuration illustrated in FIG. 5 that it is requested to install the upper electrode UE of the large planar size.

As described above, from the viewpoint of embodying the basic idea of the first embodiment, it is understood that further examination is requested for improvement when designing the actual capacitive element that reduces the noise on the transmission line without increasing the number of the capacitive elements to be arranged. Accordingly, in the first embodiment, it is devised so as to realize the capacitive element that allows exhibition of the advantageous effect of reducing the noise on the transmission line without increasing the number of the capacitive elements to be arranged. In the following, the capacitive element so devised according to the first embodiment will be described.

<Schematic Configuration of the Capacitive Element according to First Embodiment>

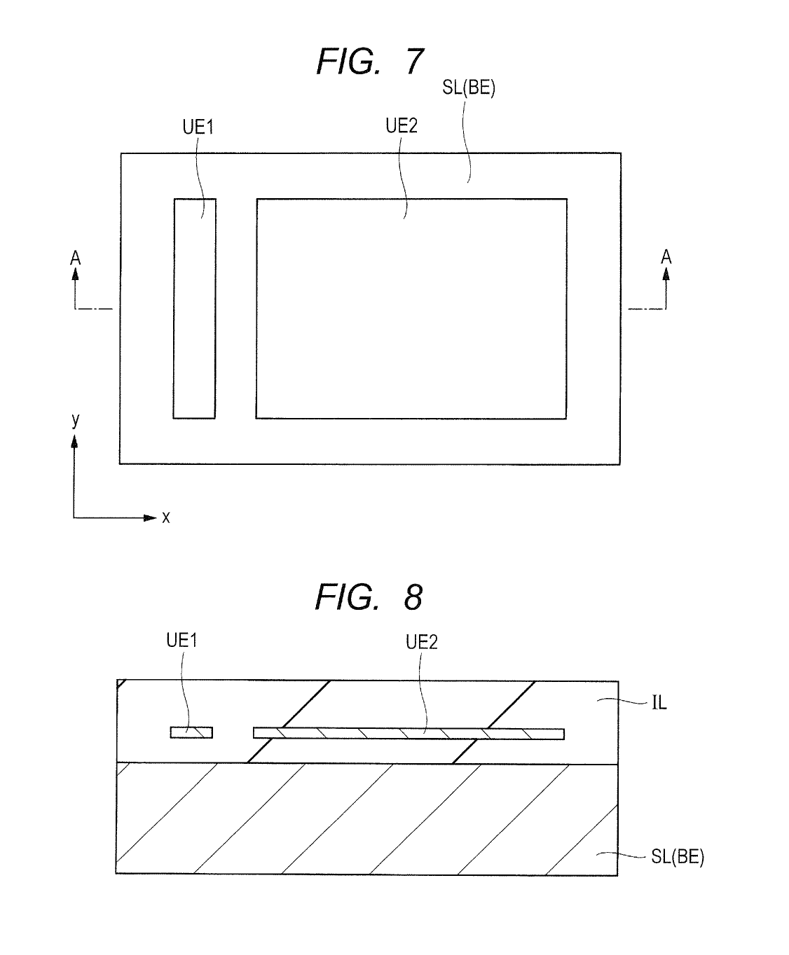

FIG. 7 is a plan view illustrating one example of a schematic configuration of the capacitive element according to the first embodiment. As illustrated in FIG. 7, the capacitive element according to the first embodiment includes the semiconductor layer SL that functions as the lower electrode BE and an upper electrode UE1 and an upper electrode UE2 are formed on the semiconductor layer SL. In this case, as illustrated in FIG. 7, the upper electrode UE1 and the upper electrode UE2 are arranged separately from each other. Further, FIG. 8 is a sectional diagram taken along the A-A line in FIG. 7. As illustrated in FIG. 8, the semiconductor layer SL in the first embodiment configures the lower electrode BE and the upper electrode UE1 and the upper electrode UE2 that are configured by, for example, conductor layers (wiring layers) are arranged on the semiconductor layer SL via a gap configured by an insulating layer IL separately from each other.

As described above, the capacitive element according to the first embodiment includes the lower electrode BE configured by the semiconductor layer SL, the upper electrode UE1 that faces the lower electrode BE, the upper electrode UE2 that faces the lower electrode BE and is arranged separately from the upper electrode UE1 and so forth.

Next, description will be made on the point that according to the above-mentioned configuration of the first embodiment, it is possible to realize the capacitive element having the frequency dependency that the capacitance value obtained when the second frequency signal that is higher in frequency than the first frequency signal has been applied becomes smaller than the capacitance value obtained when the first frequency signal has been applied.

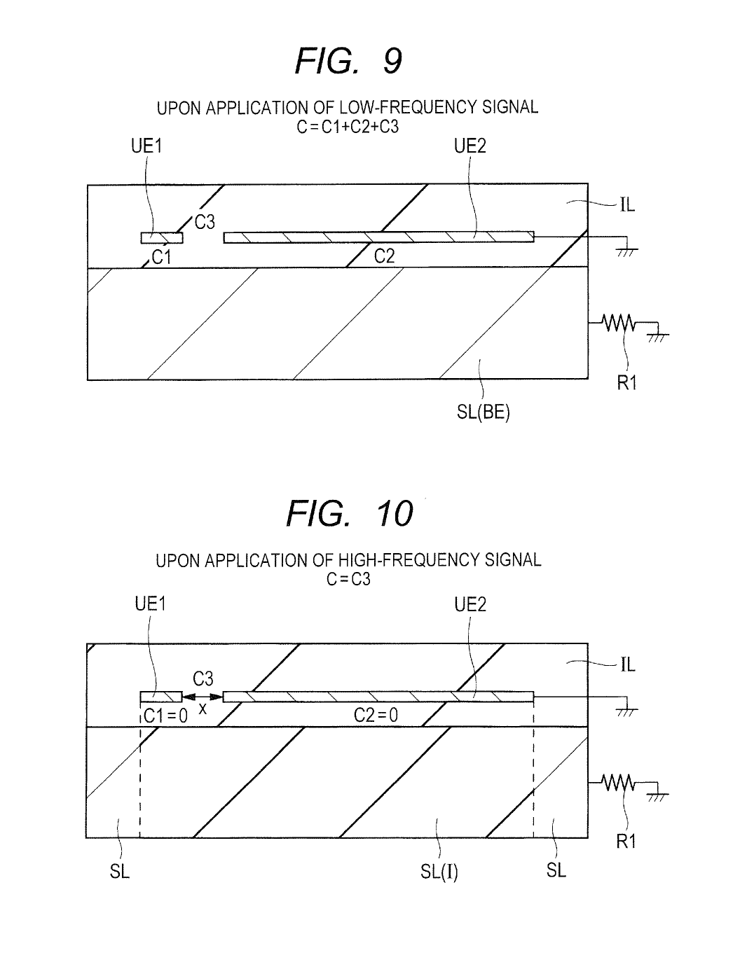

FIG. 9 is a schematic diagram illustrating one example of a case where the low frequency signal has been applied to the capacitive element according to the first embodiment. Specifically, in FIG. 9, the semiconductor layer SL that functions as the lower electrode BE is electrically coupled with ground via the parasitic resistor R1. That is, although the semiconductor layer SL is electrically coupled with ground basically, in the first embodiment, the semiconductor layer SL is electrically coupled with ground at a place separated from the capacitive element according to the first embodiment. Consequently, since the parasitic resistance of the semiconductor layer SL is increased, the semiconductor layer SL that functions as the lower electrode BE of the capacitive element is at a potential that floats relative to a ground potential of ground with the aid of the parasitic resistance. In the first embodiment, it means that the low frequency signal is applied to the upper electrode UE1 and the ground potential is applied to the upper electrode UE2. In this case, since the semiconductor layer SL acts as the conductor by the mechanism that has been described with reference to FIG. 5, the semiconductor layer SL comes to function as the lower electrode BE.

Incidentally, as illustrated in FIG. 9, in the first embodiment, the reason why the semiconductor layer SL that configures the lower electrode BE of the capacitive element is set at the potential that floats relative to the ground potential of ground is that the potentials of the semiconductor layer SL and the upper electrode UE2 are made different from each other so as to make the semiconductor layer SL and the upper electrode UE2 function as the capacitive element.

From the above, when the low frequency has been applied to the upper electrode UE1, the semiconductor layer SL functions as the lower electrode BE as illustrated in FIG. 9. From this fact, as illustrated in FIG. 9, when the low frequency signal has been applied to the upper electrode UE1, a value that a capacitance value (C1) between the upper electrode UE11 and the semiconductor layer SL, a capacitance value (C2) between the upper electrode UE2 and the semiconductor layer SL and a capacitance value (C3) between the upper electrode UE1 and the upper electrode UE2 have been added together is obtained as the capacitance value of the capacitive element according to the first embodiment.

In particular, in the capacitive element according to the first embodiment, for example, as illustrated in FIG. 7, even in a state of keeping the planar size of the upper electrode UE1 small, the value that the capacitance value (C1), the capacitance value (C2) and the capacitance value (C3) have been added together is obtained as the capacitance value obtained when the low frequency signal has been applied to the upper electrode UE1 as illustrated in FIG. 9. From this fact, in the capacitive element according to the first embodiment, it becomes possible to ensure the capacitance value that is sufficient for inducing reflection of the low frequency signal while keeping the planar size of the upper electrode UE1 to which the low frequency signal is to be applied small. Therefore, according to the capacitive element of the first embodiment, it becomes possible to realize the configuration that the upper electrode UE1 to be electrically coupled with the signal line is arranged without sacrificing the high-density arrangement of the signal lines. That is, the capacitive element according to the first embodiment is useful in the point that it is possible to realize the capacitance value that is sufficient for inducing reflection of the low frequency signal while sufficiently fulfilling the constraints on actual design.

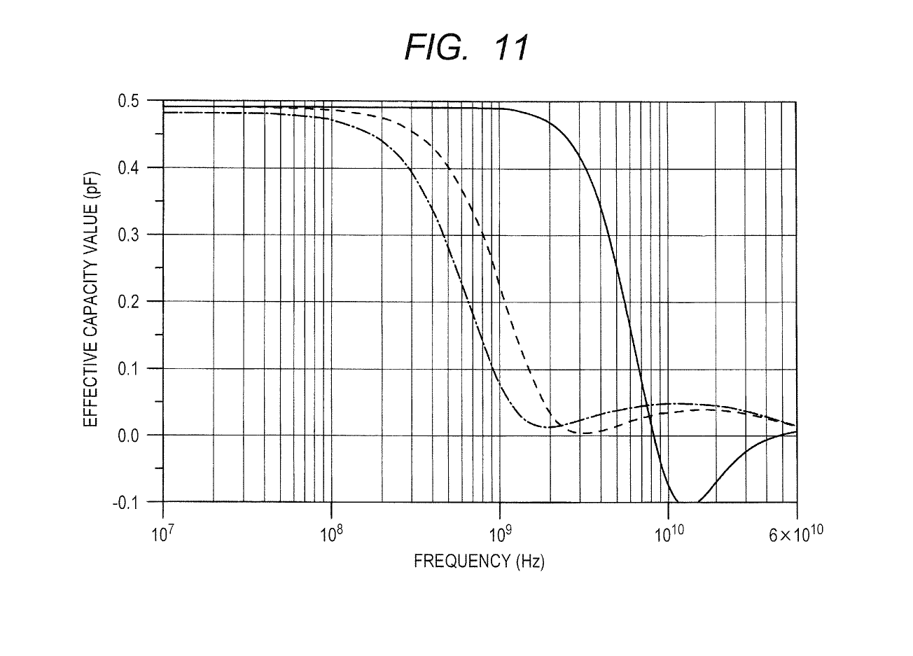

On the other hand, FIG. 10 is a schematic diagram illustrating one example of a case where the high frequency signal has been applied to the capacitive element according to the first embodiment. Specifically, in FIG. 10, the semiconductor layer SL is at the potential that floats relative to the ground potential of ground with the aid of the parasitic resistance. In the first embodiment, in this state, the high frequency signal is applied to the upper electrode UE1 and the ground potential is applied to the upper electrode UE1. In this case, in the first embodiment, design of a distance x between the upper electrode UE1 and the upper electrode UE2 is important. This is because it is possible to adjust an impedance (1/ωC3) between the upper electrode UE1 and the upper electrode UE2 small by appropriately designing the distance x between the upper electrode UE1 and the upper electrode UE2. Then, further, in application of the high frequency signal, it is possible to make the impedance (1/ωC3) between the upper electrode UE1 and the upper electrode UE2 small for the high frequency signal owing to the synergistic effect between the above-mentioned point and the point that “G)” is increased for the high frequency signal. Then, that it is possible to make the impedance (1/ωC3) between the upper electrode UE1 and the upper electrode UE2 small for the high frequency signal means that it becomes easy to transmit the high frequency signal from the upper electrode UE1 to the upper electrode UE2. In this case, although the high frequency signal is applied to the upper electrode UE1 basically, it also means that the high frequency signal is transmitted also to the upper electrode UE2. Consequently, it becomes difficult for the carriers contained in the semiconductor layer SL(I) to follow the high frequency signal not only on the part of the semiconductor layer SL(I) that overlaps the upper electrode UE1 planarly, but also on the part of the semiconductor layer SL(I) that overlaps the upper electrode UE2 planarly and it becomes possible to make the semiconductor layer SL(I) function as the insulator. Thereby, in the capacitive element according to the first embodiment, when the high frequency signal has been applied to the upper electrode UE1, both of the capacitance value (C1) and the capacitance value (C1) are reduced to “zeros”. For this reason, when the high frequency signal has been applied to the upper electrode UE1 as illustrated in FIG. 10, only the capacitance value (C3) between the upper electrode UE1 and the upper electrode UE2 is obtained as the capacitance value of the capacitive element according to the first embodiment. In this case, since the upper electrode UE1 and the upper electrode UE2 are made thin, it is possible to make the capacitance value (C3) small.

From the above, it is understood that according to the first embodiment, it is possible to realize the capacitive element that has the frequency dependency that the capacitance value (C3) obtained when the high frequency signal (the second frequency signal) that is higher in frequency than the low frequency signal has been applied becomes smaller than the capacitance value (C1+C2+C3) obtained when the low frequency signal (the first frequency signal) has been applied. In particular, it is possible to make the capacitance value obtained when the high frequency signal has been applied smaller than the capacitance value obtained when the low frequency has been applied by making the planar size of the upper electrode UE2 to which the ground potential is to be supplied larger than the planar size of the upper electrode UE1 to which the signal is to be applied.

FIG. 11 is a graph illustrating one example of a result of simulation performed on the frequency dependency of the capacitive element according to the first embodiment. In FIG. 11, the horizontal axis indicates a frequency (Hz) and the vertical axis indicates an effective capacity value (pF) of the capacitive element according to the first embodiment.

As illustrated in FIG. 11, it is seen that while when the frequency is low, the effective capacity value is large, the effective capacity value is decreased as the frequency becomes high. Therefore, it is understood that the fact that according to the first embodiment, it is possible to realize the capacitive element that has the frequency dependency that the capacitance value obtained when the high frequency signal that is higher in frequency than the low frequency signal has been applied becomes smaller than the capacitance value obtained when the low frequency signal has been applied has been proven also from the result of simulation.

Incidentally, in FIG. 11, a one-dot-chain curved line indicates a case where the impurity concentration of conductive impurities introduced into the semiconductor layer is low and a dotted curved line indicates a case where the impurity concentration of the conductive impurities introduced into the semiconductor layer is higher than the impurity concentration indicated by the one-dot-chain curved line. Further, a solid curved line indicates a case where the impurity concentration of the conductive impurities introduced into the semiconductor layer is higher than the impurity concentration indicated by the dotted curved line. From the above, it is understood that a fluctuation start frequency at which a fluctuation in effective capacity value is started changes by changing the impurity concentration of the conductive impurities introduced into the semiconductor layer. Specifically, the higher the impurity concentration of the conductive impurities introduced into the semiconductor layer becomes, the higher the fluctuation start frequency becomes. Therefore, according to the capacitive element of the first embodiment, it is possible to set the fluctuation start frequency to a desirable value by adjusting the impurity concentration of the conductive impurities introduced into the semiconductor layer that configures the lower electrode. In this case, the conductive impurities introduced into the semiconductor layer may be p-type impurities and/or n-type impurities. According to the capacitive element of the first embodiment, since it is possible to appropriately set the fluctuation start frequency at which the fluctuation in effective capacity value is started by adjusting the impurity concentration of the conductive impurities introduced into the semiconductor layer in this way, it is possible to obtain an advantage that it is possible to provide the capacitive element that is high in degree of design freedom.

As described above, according to the capacitive element of the first embodiment, it is possible to embody the basic idea of the first embodiment, and thereby it is possible to eliminate the side effect itself that is called amplification of the reflected signal and the inversion signal which would occur when the high frequency signal has been applied. Consequently, it is possible to reduce the noise on the transmission line without increasing the number of the capacitive elements to be arranged.

### <Configuration of the Semiconductor Device in First Embodiment>

Then, one example of a configuration of the semiconductor device that has adopted the above-mentioned capacitive element according to the first embodiment will be described with reference to the drawings.

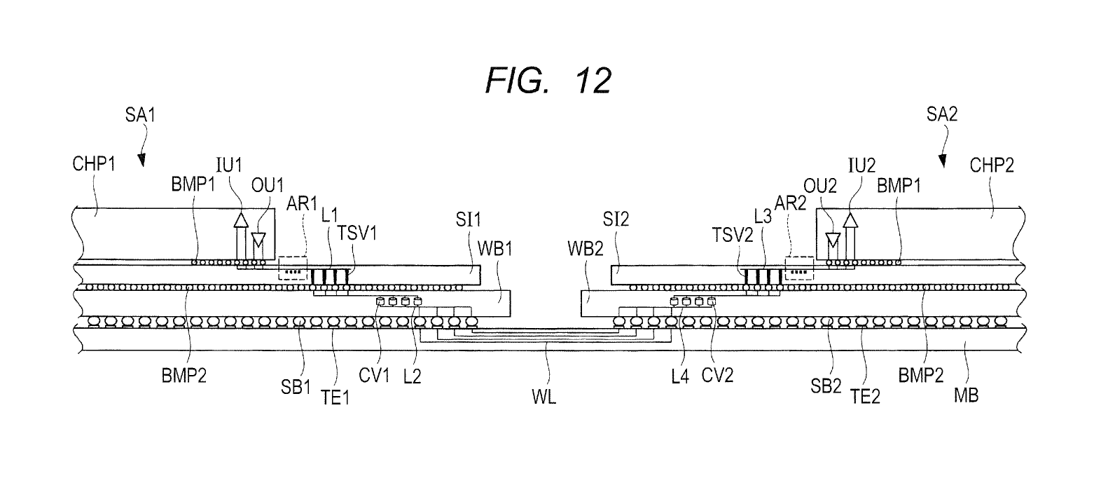

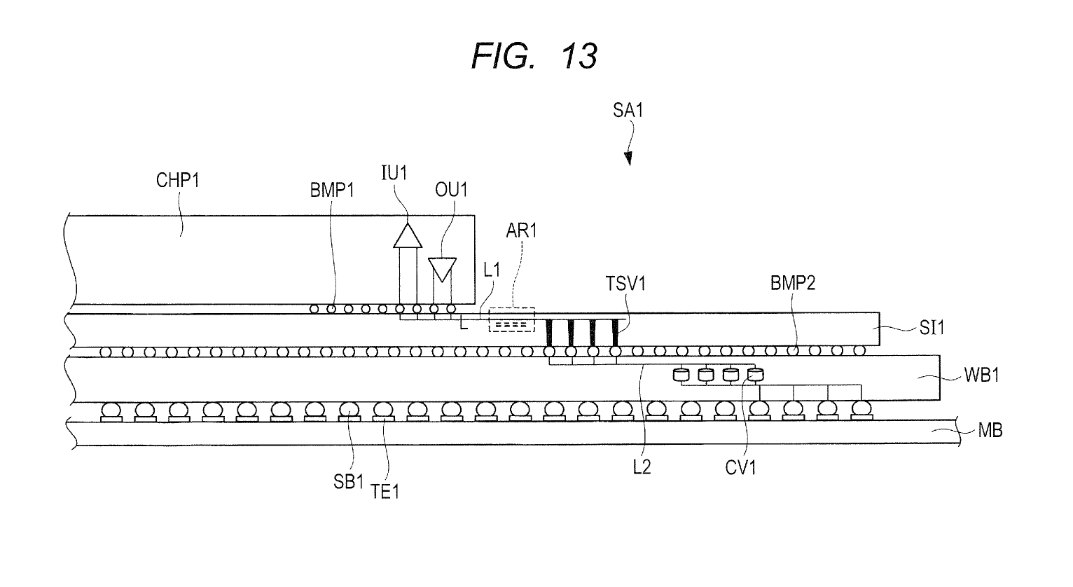

FIG. 12 is a diagram schematically illustrating one example of a coupling configuration between a semiconductor device SA1 and a semiconductor device SA2 that have been loaded on the mounting board MB. In addition, FIG. 13 is a diagram schematically illustrating one example of the configuration of the semiconductor device SA1 that has been loaded on the mounting board MB. As illustrated in FIG. 12, the semiconductor device SA1 and the semiconductor device SA2 are loaded on the mounting board MB so as to be separated from each other. Specifically, when focusing on the semiconductor device SA1 illustrated in FIG. 12 and FIG. 13, the semiconductor device SA1 includes a wiring board WB1, a silicon interposer SI1 loaded on the wiring board WB1, a semiconductor chip CHP1 loaded on the silicon interposer SI1 and so forth. Here, the plurality of wiring lines L2 are formed in the wiring board WB1 and a capacitor via CV1 that functions as the capacitive element and a plug is also formed in the wiring board WB1. Then, a plurality of solder balls SB1 are formed on a back face of the wiring board WB1 and each of the plurality of solder balls SB1 is coupled with each of a plurality of terminals TE1 that are formed on a front face of the mounting board MB.

Next, the plurality of wiring lines L1 and a through-via TSV1 are formed in the silicon interposer SI1. Then, a plurality of bump electrodes BMP2 are formed on a back face of the silicon interposer SI1. The wiring lines L1 that are formed in the silicon interposer SI1 and the wiring lines L2 that are formed in the wiring board WB1 are electrically coupled together via the plurality of bump electrodes BMP2.

Then, the input unit IU1 and the output unit OU1 are formed in the semiconductor chip CHP1. Then, a plurality of bump electrodes BMP1 are formed on a back face of the semiconductor chip CHP1, and the input unit IU1 and the output unit OU1 that are formed in the semiconductor chip CHP1 and the wiring lines L1 that are formed in the silicon interposer SI1 are electrically coupled together via the plurality of bump electrodes BMP2. Incidentally, though not illustrated in the drawing, in the semiconductor device SA1, for example, the stacked memory SM such as that illustrated in FIG. 4 is also loaded on the silicon interposer SI1, in addition to the semiconductor chip CHP1.

In addition, in FIG. 12, in the first embodiment, the capacitive element according to the first embodiment is formed within an area RA1 in the silicon interposer SI1. Then, when a wavelength of the low frequency (the first frequency signal) is designated by λ, the capacitive element according to the first embodiment is arranged at a position that is separated from the input unit IU1 or the output unit OU1 by λ/4. The semiconductor device SA1 according to the first embodiment is configured in the above-mentioned manner.

Likewise, when focusing on the semiconductor device SA2 illustrated in FIG. 12, the semiconductor device SA2 includes a wiring board WB2, a silicon interposer SI2 that has been loaded on the wiring board WB2, a semiconductor chip CHP2 that has been loaded on the silicon interposer SI2 and so forth. Here, a plurality of wiring lines L4 are formed in the wiring board WB2 and a capacitor via CV2 that functions as the capacitive element and the plug is also formed in the wiring board WB2. Then, a plurality of solder balls SB2 are formed on a back face of the wiring board WB2 and each of the plurality of solder balls SB2 is coupled with each of a plurality of terminals TE2 formed on a front face of the mounting board MB.

Next, a plurality of wiring lines L3 and a through-via TSV2 are formed in the silicon interposer SI2. Then, a plurality of bump electrodes BMP4 are formed on a back face of the silicon interposer SI2. The wiring lines L3 formed in the silicon interposer SI2 and the wiring lines L4 formed in the wiring board WB2 are electrically coupled together via the plurality of bump electrodes BMP4. In particular, in FIG. 12, in the first embodiment, the capacitive element according to the first embodiment is formed within an area AR2 in the silicon interposer SI2.

Then, an input unit IU2 and an output unit OU2 are formed in the semiconductor chip CHP2. Then, a plurality of bump electrodes BMP3 are formed on a back face of the semiconductor chip CHP2, and the input unit IU2 and the output unit OU2 formed in the semiconductor chip CHP2 and the wiring lines L3 formed in the silicon interposer SI2 are electrically coupled together via the plurality of bump electrodes BMP3. Incidentally, though not illustrated in the drawing, the stacked memory SM such as that illustrated in FIG. 4 is also loaded on the silicon interposer SI2 in addition to the semiconductor chip CHP2.

In addition, in FIG. 12, in the first embodiment, the capacitive element according to the first embodiment is formed within the area AR2 in the silicon interposer SI2. Then, when the wavelength of the low frequency signal (the first frequency signal) is designated by λ, the capacitive element according to the first embodiment is arranged at a position that is separated from the input unit IU2 or the output unit OU2 by λ/4. The semiconductor device SA2 according to the first embodiment is configured in the above-mentioned manner.

The semiconductor device SA1 and the semiconductor device SA2 that have been configured in this way are loaded on the mounting board MB and are electrically coupled together via a plurality of wiring lines WL formed in the mounting board MB. Accordingly, this means that the semiconductor device SA1 and the semiconductor device SA2 are electrically coupled together. Describing in detail, it means that the input unit IU1 formed in the semiconductor chip CHP1 is electrically coupled with the output unit OU2 formed in the semiconductor chip CHP2, and the output unit OU1 formed in the semiconductor chip CHP1 is electrically coupled with the input unit IU2 formed in the semiconductor chip CHP2. In particular, in FIG. 12, the transmission line ETL is configured by the wiring lines L1 formed in the silicon interposer SI1, the wiring lines L2 formed in the wiring board WB1, the wiring lines WL formed in the mounting board MB, the wiring lines L4 formed in the wiring board WB2, the wiring lines L3 formed in the silicon interposer SI2 and so forth. Thus, it means that the semiconductor chip CHP1 and the semiconductor chip CHP2 are electrically coupled together via the transmission line ETL.

### <Planar Configuration of the Capacitive Element>

Next, one example of a planar layout configuration of the capacitive element according to the first embodiment that is formed within the area AR2 illustrated in FIG. 12 and FIG. 13 will be described.

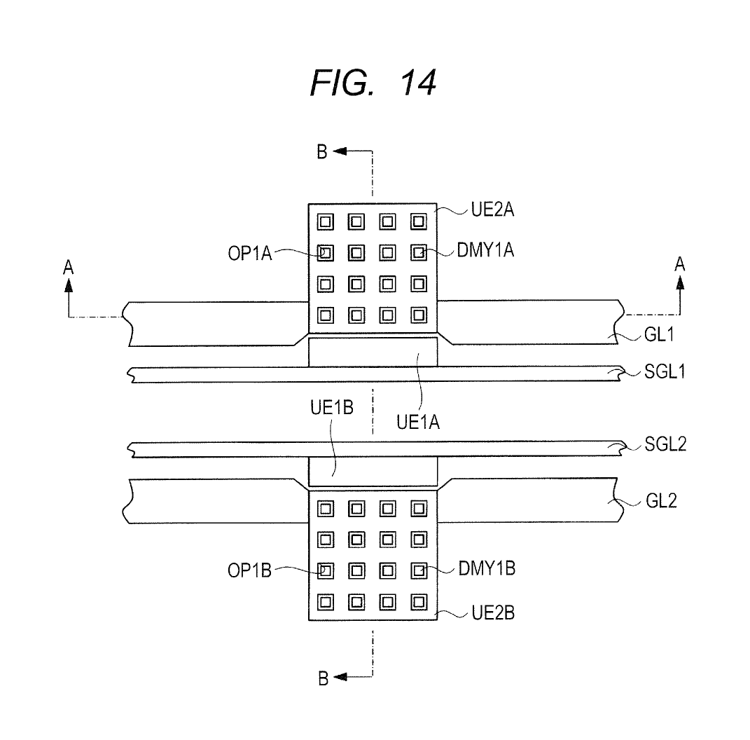

FIG. 14 is a plan view illustrating one example of the planar layout configuration of the capacitive element according to the first embodiment. As illustrated in FIG. 14, a ground line GL1 that extends in an x direction and a signal line SGL1 that extends also in the x direction are arranged in parallel with and separately from each other. Likewise, a ground line GL2 that extends in the x direction and a signal line SGL2 that extends also in the x direction are arranged in parallel with and separately from each other. Here, when focusing on the ground line GL1 and the signal line SGL1, an upper electrode UE1A is coupled to the signal line SGL1 and an upper electrode UE2A is coupled to the ground line GL1. Then, the upper electrode UE1A and the upper electrode UE2A are arranged at mutually facing positions and a planar size of the upper electrode UE2A is made larger than a planar size of the upper electrode UE1A. Further, a plurality of openings OP1A are formed in the upper electrode UE2A and dummy patterns (conductor patterns that do not function as wiring lines) DMY1A that do not function as wiring lines are arranged so as to be respectively contained in the plurality of openings OP1A. The upper electrode UE1A and the upper electrode UE2A that configure one capacitive element according to the first embodiment are arranged according to a planar layout in this way.

Likewise, when focusing on the ground line GL2 and the signal line SGL2, an upper electrode UE1B is coupled to the signal line SGL2 and an upper electrode UE2B is coupled to the ground line GL2. Then, the upper electrode UE1B and the upper electrode UE2B are arranged at mutually facing positions and a planar size of the upper electrode UE2B is made larger than a planar size of the upper electrode UE1B. Further, a plurality of openings OP1B are formed in the upper electrode UE2B and dummy patterns DMY1B are arranged so as to be respectively contained in the plurality of openings OP1B respectively. The upper electrode UE1B and the upper electrode UE2B that configure one more capacitive element according to the first embodiment are arranged also according to the planar layout in this way.

### <First Sectional Configuration of the Capacitive Element>

Then, one example of a sectional configuration of the capacitive element according to the first embodiment that is formed within the area AR1 illustrated in FIG. 12 and FIG. 13 will be described.]

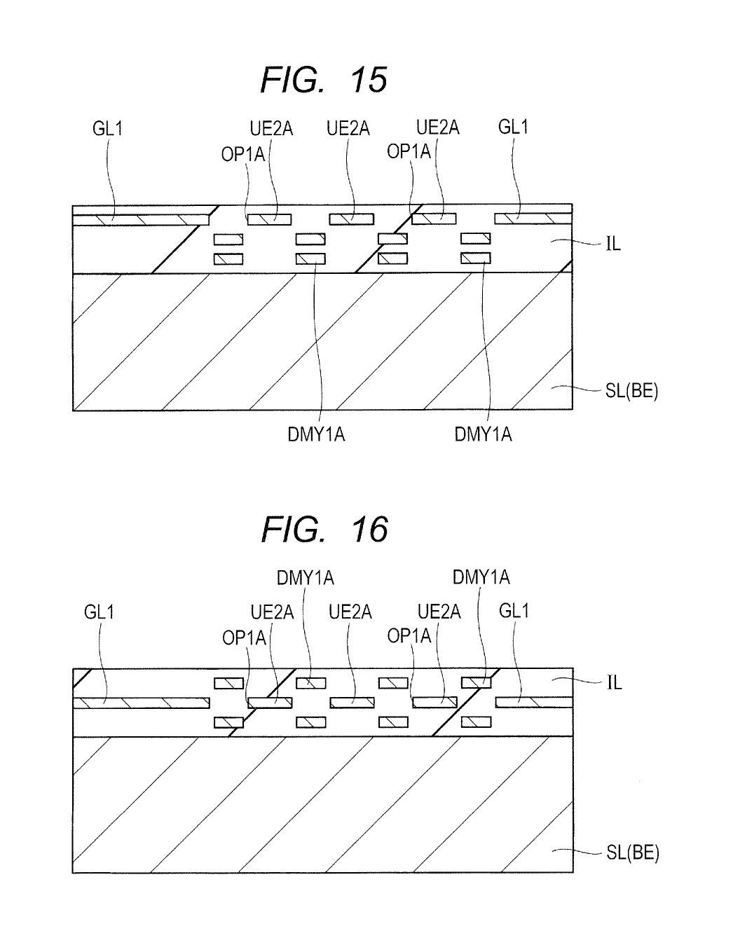

FIG. 15 is a sectional diagram taken along the A-A line in FIG. 14. As illustrated in FIG. 15, a plurality of wiring layers are formed over the semiconductor layer SL that functions as the lower electrode BE of the capacitive element according to the first embodiment via the insulating layer IL. Then, in FIG. 15, the ground line GL1 and the upper electrode UE2A are arranged in an uppermost wiring layer in the plurality of wiring layers. Further, the plurality of openings OP1A are formed in the upper electrode UE2A and the dummy patterns DMY1A are formed in the wiring layer that is located lower than the uppermost wiring layer such that each of the dummy patterns DMY1A overlaps each of the plurality of openings OP1A planarly.

In the first embodiment, as illustrated in FIG. 15, one example that the ground line GL1 and the upper electrode UE2A are arranged in the uppermost wiring layer in the plurality of wiring layers has been described. However, the arrangement is not limited to the above and, for example, the ground line GL1 and the upper electrode UE2A may be arranged in an intermediate wiring layer in the plurality of wiring layers (a first altered example) and the ground line GL1 and the upper electrode UE2A may be arranged in a lowermost wiring layer in the plurality of wiring layers (a second altered example). In the following, sectional configurations of the first altered example and the second altered example will be specifically described with reference to the drawings.

### First Altered Example

FIG. 16 is a sectional diagram illustrating one example of the first altered example and corresponding to the section taken along the A-A line in FIG. 14. As illustrated in FIG. 16, the plurality of wiring layers are formed over the semiconductor layer SL that functions as the lower electrode BE of a capacitive element according to the first altered example via the insulating layer IL. Then, in FIG. 16, the ground layer GL1 and the upper electrode UE2A are arranged in the intermediate wiring layer in the plurality of wiring layers. Further, the plurality of openings OP1A are formed in the upper electrode UE2A, and the dummy patterns DMY1A are formed in the wiring layer (the uppermost layer) that is located higher than the intermediate wiring layer and the dummy patterns DMY1A are also formed in the wiring layer (the lowermost layer) that is located lower than the intermediate wiring layer such that each of the dummy patterns DMY1A overlaps each of the plurality of openings OP1A planarly.

### Second Altered Example

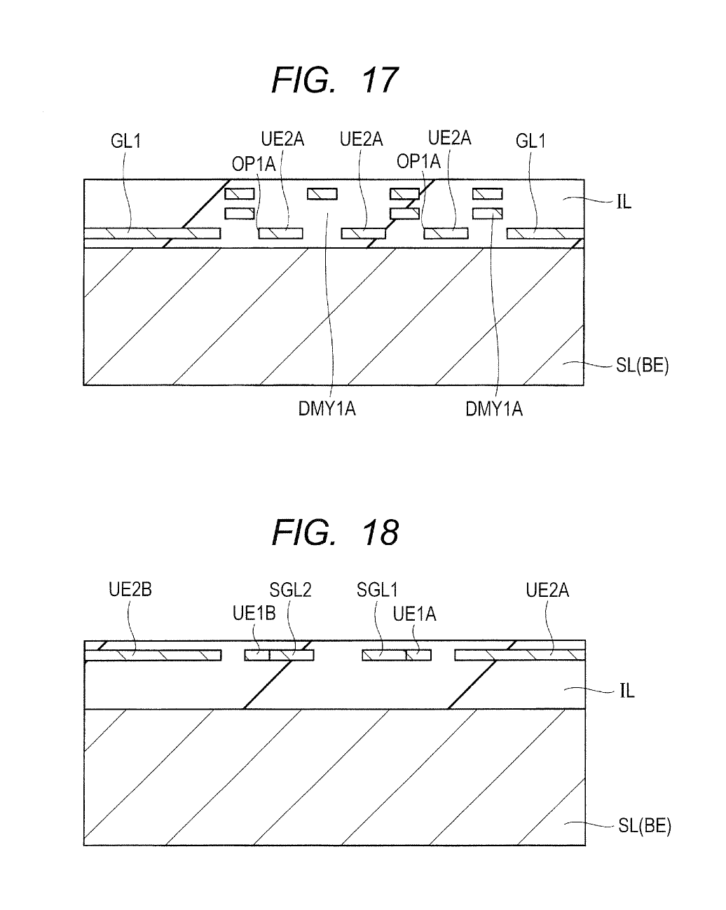

FIG. 17 is a sectional diagram illustrating one example of the second altered example and corresponding to the section taken along the A-A line in FIG. 14. As illustrated in FIG. 17, the plurality of wiring layers are formed over the semiconductor layer SL that functions as the lower electrode BE of a capacitive element according to the second altered example via the insulating layer IL. Then, in FIG. 17, the ground layer GL1 and the upper electrode UE2A are arranged in the lowermost wiring layer in the plurality of wiring layers. Further, the plurality of openings OP1A are formed in the upper electrode UE2A, and the dummy patterns DMY1A are formed in the wiring layer that is located higher than the lowermost wiring layer such that each of the dummy patterns DMY1A overlaps each of the plurality of openings OP1A planarly.

### <Second Sectional Configuration of the Capacitive Element>

FIG. 18 is a sectional diagram taken along the B-B line in FIG. 14. As illustrated in FIG. 18, the upper electrode UE2A of one capacitive element and the upper electrode UE2B of the other capacitive element are formed over the semiconductor layer SL that functions as the lower electrode BE of the capacitive element according to the first embodiment via the insulating layer IL. Then, as illustrated in FIG. 18, the signal line SGL1 that has been coupled with the upper electrode UE1A and the signal line SGL2 that has been coupled with the upper electrode UE1B are arranged in the same layer as the upper electrode UE2A and the upper electrode UE2B.

### Characteristic Points of First Embodiment

Next, the characteristic points of the first embodiment will be described. A first characteristic point of the first embodiment lies in the point that the capacitive element that has the frequency dependency that the capacitance value obtained when the high frequency signal (the second frequency signal) that is higher in frequency than the low frequency signal has been applied becomes smaller than the capacitance value obtained when the low frequency signal (the first frequency signal) has been applied is used.

Thereby, it is possible to induce cancellation of the reflected signal and the inversion signal for the low frequency signal and therefore it is possible to reduce the noise on the transmission line caused by the reflected signal of the low frequency signal. On the other hand, since the capacitance value is reduced and, as a result, the inversion signal is not generated for the high frequency signal, it is possible to suppress the side effect that is called the amplification of the reflected signal of the high frequency signal and the inversion signal. Consequently, according to the first characteristic point of the first embodiment, it is possible to eliminate the above-mentioned side effect itself and, as a result, it is possible to reduce the noise on the transmission line without increasing the number of the capacitive elements to be arranged.

Then, a second characteristic point of the first embodiment lies in, for example, the schematic configuration of the capacitive element that has embodied the above-mentioned first characteristic point. Specifically, the second characteristic point of the first embodiment lies in the point that, for example, as illustrated in FIG. 7 to FIG. 10, the capacitive element that includes the lower electrode BE configured by the semiconductor layer SL, the upper electrode UE1 that faces the lower electrode BE, the upper electrode UE2 arranged so as to face the lower electrode BE and to be separated from the upper electrode UE1 and so forth is adopted.

Thereby, for example, when the low frequency signal has been applied to the upper electrode UE1 as illustrated in FIG. 9, the semiconductor layer SL functions as the lower electrode BE. For this reason, the value that the capacitance value (C1) between the upper electrode UE1 and the semiconductor layer SL, the capacitance value (C2) between the upper electrode UE1 and the semiconductor layer SL and the capacitance value (C3) between the upper electrode UE1 and the upper electrode UE2 have been added together is obtained as the capacitance value of the capacitive element according to the first embodiment. On the other hand, for example, when the high frequency signal has been applied to the upper electrode UE1 as illustrated in FIG. 10, the semiconductor layer SL does not function as the lower electrode BE and therefore the capacitance value (C3) between the upper electrode UE1 and the upper electrode UE2 is obtained as the capacitance value of the capacitive element according to the first embodiment. That is, when the high frequency signal has been applied to the upper electrode UE1, the capacitance value (C1) between the upper electrode UE2 and the semiconductor layer SL and the capacitance value (C2) between the upper electrode UE2 and the semiconductor layer SL are reduced to “zeros”.

Therefore, according to the second characteristic point of the first embodiment, it is understood that it is possible to realize the capacitive element that has the frequency dependency that the capacitance value (C3) obtained when the high frequency signal that is higher in frequency than the low frequency signal has been applied becomes smaller than the capacitance value (C1+C2+C3) obtained when the low frequency signal has been applied. In particular, it is desirable to make the planar size of the upper electrode UE2 to which the ground potential is to be supplied larger than the planar size of the upper electrode UE1 to which the signal is to be applied in order to make the capacitance value obtained when the high frequency signal has been applied smaller than the capacitance value obtained when the low frequency signal has been applied. Incidentally, since according to the second characteristic point of the first embodiment, it is possible to configure the capacitance value obtained when the low frequency signal has been applied by C1+C2+C3, it is possible to ensure the large capacitance value without increasing the planar size of the capacitive element. This means that upsizing of the capacitive element that has been done so far in order to ensure the large capacitance value is eliminated. Thereby, it is possible to promote miniaturization of the semiconductor device including the capacitive element. From the above, according to the second characteristic point of the first embodiment, it is possible to reduce the noise on the transmission line without increasing the planer size of the capacitive element and the number of the capacitive elements to be arranged. Consequently, according to the second characteristic point of the first embodiment, it is possible to obtain such a noticeable advantageous effect that it is possible to promote improvement of performance of the semiconductor device while promoting miniaturization of the semiconductor device.

Next, a third characteristic point of the first embodiment lies in the point that it is possible to freely set the impurity concentration of the conductive impurities introduced into the semiconductor layer SL that functions as the lower electrode BE of the capacitive element. Thereby, according to the third characteristic point of the first embodiment, it is possible to freely design the fluctuation start frequency at which the fluctuation in capacitance value of the capacitive element is started. This is because, for example, as illustrated in FIG. 11, the fluctuation start frequency at which the fluctuation in capacitance value of the capacitive element is started changes depending on the impurity concentration of the conductive impurities introduced into the semiconductor layer SL. Therefore, according to the capacitive element of the first embodiment, it is possible to realize the target fluctuation start frequency by appropriately adjusting the impurity concentration of the conductive impurities introduced into the semiconductor layer SL. From the above, according to the third characteristic point of the first embodiment, it is possible to obtain such an advantage that it is possible to improve the degree of freedom in designing the capacitive element according to the first embodiment.

Further, a fourth characteristic point of the first embodiment lies in the point that the degree of freedom that as the arrangement position of each upper electrode (UE1A, UE1B, UE2A, UE2B) of the capacitive element, the upper electrode may be arranged in any of the uppermost, the intermediate layer and the lowermost layer in the plurality of wiring layers is imparted to the capacitive element. Thereby, according to the fourth characteristic point of the first embodiment, it is possible to freely design the fluctuation start frequency at which the fluctuation in capacitance value of the capacitive element is started similarly to the advantageous effect brought about by the above-mentioned third characteristic point. This is because the fluctuation start frequency at which the fluctuation in capacitance value of the capacitive element is started changes not only depending on the impurity concentration of the conductive impurities introduced into the semiconductor layer SL, but also depending on the distance between the semiconductor layer SL that functions as the lower electrode BE of the capacitive element and the upper electrode of the capacitive element. For example, the more the distance between the semiconductor layer SL and each of the upper electrodes is increased, the higher the fluctuation start frequency becomes. Accordingly, when it is wished to make the fluctuation start frequency high, it is also effective to design so as to arrange the upper electrodes of the capacitive element in the uppermost wiring layer in the plurality of wiring layers, not limited to increasing the impurity concentration of the conductive impurities introduced into the semiconductor layer SL. In other words, when it is wished to make the fluctuation start frequency low, it is effective to design so as to arrange the upper electrodes of the capacitive element in the lowermost wiring layer in the plurality of wiring layers, not limited to decreasing the impurity concentration of the conductive impurities introduced into the semiconductor layer SL. That is, according to the capacitive element of the first embodiment, it is possible to obtain such an advantageous effect that it is possible to greatly improve the degree of freedom in designing the capacitive element having the desirable fluctuation start frequency owing to the synergistic effect between adjustment of the impurity concentration of the conductive impurities introduced into the semiconductor layer SL(the third characteristic point) and adjustment of the arrangement position of each upper electrode (the fourth characteristic point).

Then, a fifth characteristic point of the first embodiment lies in the point that, for example, as illustrated in FIG. 14 to FIG. 17, the plurality of openings (OP1A, OP1B) are formed in the upper electrode (UE2A, UE2B) and the dummy patterns (DMY1A, DMY1B) are arranged in the wiring layer that is different from the wiring layer that the upper electrode is formed so as to be contained in the plurality of openings (OP1A, OP1B) in planar view.

Thereby, according to the fifth characteristic point of the first embodiment, first, it is possible to suppress a variation in wiring density among the wiring layers by arranging the dummy patterns (DMY1A, DMY1B) also in the wiring layer that the upper electrode (UE2A, UE2B) is not arranged. Consequently, it is possible to suppress dishing that would occur due to the variation in wiring density, for example, when forming the wiring lines by a damascene method and thereby it is possible to form highly reliable wiring lines (a first advantage).

In addition, according to the fifth characteristic point of the first embodiment, it is possible to make the fluctuation in capacitance value gentle (a second advantage). This is because the dummy patterns (DMY1A, DMY1B) are arranged in the wiring layer that is different from the wiring layer that the upper electrode (UE2A, UE2B) is arranged. That is, this is because not only the capacitance value between the upper electrode (UE2A, UE2B) of the capacitive element and the semiconductor layer SL, but also the capacitance value between the upper electrode (UE2A, UE2B) and the dummy pattern (DYM1A, DMY1B) and the capacitance value between the dummy pattern (DMY1A, DMY1B) and the semiconductor layer SL contribute to attainment of the gentle fluctuation in capacitance value as capacitive coupling. That is, this is because since the fluctuation start frequency also depends on the inter-electrode distance, that also the capacitance values that are mutually different in inter-electrode distance contribute to attainment of the gentle fluctuation in capacitance value means that the fluctuation in capacitance value becomes more gentle by superimposition of these capacitance values than that attained in a case of having the capacitance value of a single inter-electrode distance.

Thereby, according to the fifth characteristic point of the first embodiment, it is possible to widen a range of frequencies at which the inversion signal is generated by the capacitive element. For example, when the capacitance value of the capacitive element fluctuates steeply, reflection by the capacitive element does not occur even with a signal of a frequency that slightly deviates from a frequency at which the inversion signal is generated owing to reflection by the capacitive element and designing of the capacitive element becomes difficult. In particular, in a digital signal (a rectangular signal) that includes mutually different frequency components, it is requested to ensure the frequency band that the inversion signal is generated and also from this viewpoint, it is desirable to avoid a steep fluctuation in capacitance value of the capacitive element.

On the contrary, that the fluctuation in capacitance value becomes gentle means that reflection by the capacitive element occurs even with the signal of the frequency that slightly deviates from the frequency at which the inversion signal is generated. This means that designing of the capacitive element is facilitated and it is also possible to sufficiently cope with the digital signal. Accordingly, when designing the capacitive element, it is designable that the fluctuation in capacitance value be gentle in designing the capacitive element.

In regard to this point, according to the fifth characteristic point of the first embodiment, it becomes possible to make the fluctuation in capacitance value gentle and therefore it is possible to obtain such an advantage that designing of the capacitive element that copes with the digital signal is facilitated.

### Second Embodiment

As described in the first embodiment, it is desirable to make the fluctuation in capacitance value gentle from the viewpoint of facilitating designing of the capacitive element having the frequency dependency. In regard to this point, devising is made on the basis of the fifth characteristic point also in the first embodiment. In addition, since it has been found that it is also effective to devise the shape of the capacitive element in order to make the fluctuation in capacitance value gentle as a result of the examination done by the inventors and others of the present invention, points for devising will be described in the second embodiment.

### <Shape Devising of the Capacitive Element>

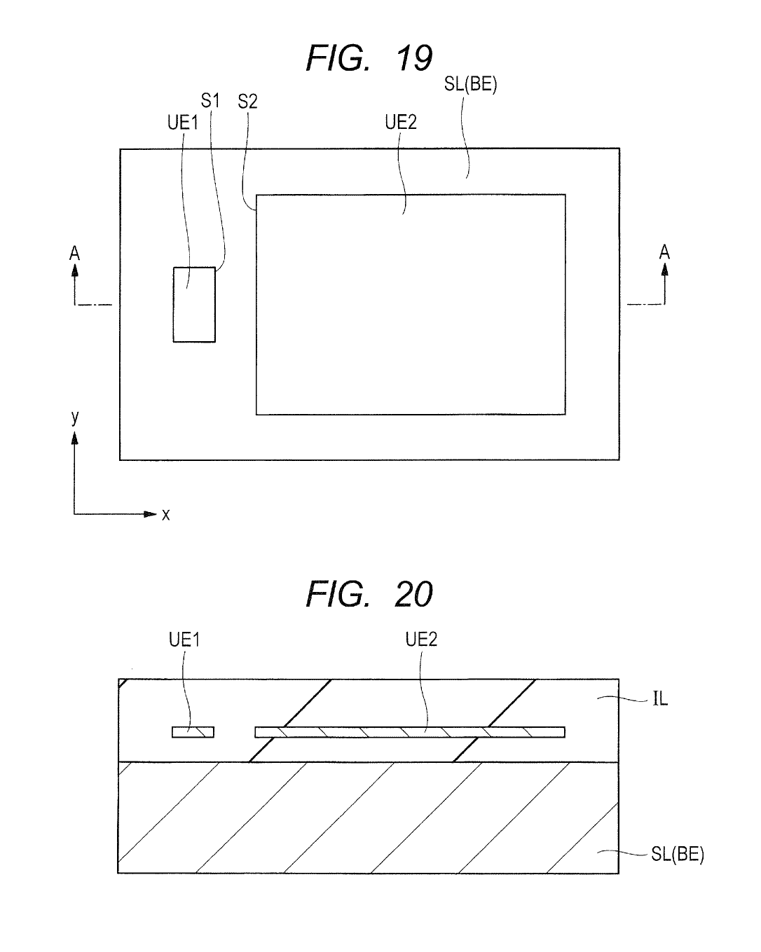

FIG. 19 is a plan view illustrating one example of a schematic configuration of a capacitive element according to the second embodiment. As illustrated in FIG. 19, in the capacitive element according to the second embodiment, the upper electrode UE1 and the upper electrode UE2 that are mutually different in planar size are arranged on the semiconductor layer SL that functions as the lower electrode BE at mutually adjacent positions separately from each other. In particular, the planer size of the upper electrode UE2 is made greatly larger than the planar size of the upper electrode UE1.

As illustrated in FIG. 19, the upper electrode UE1 includes a facing side S1 that faces the upper electrode UE2 and the upper electrode UE2 includes a facing side S2 that faces the upper electrode UE1 in planar view. In this case, a characteristic point of the second embodiment lies in the point that a length (the length in a y direction) of the facing side S1 is different from a length (the length in the y direction) of the facing side S2. Specifically, the length of the facing side S1 is made shorter than the length of the facing side S2. In other words, the length of the facing side S2 is made longer than the length of the facing side S1. According to the capacitive element of the second embodiment, although it is possible to make the fluctuation in capacitance value gentle by devising the shapes of the upper electrodes in this way, a mechanism thereof will be described later.

Next, FIG. 20 is a sectional diagram taken along the A-A line in FIG. 19. As illustrated in FIG. 20, the upper electrode UE1 configured by a conductor film and the upper electrode UE2 also configured by a conductor film are arranged on the semiconductor layer SL that functions as the lower electrode BE in the same layer via, for example, the insulating layer IL configured by a silicon oxide film separately from each other.

<Mechanism that Makes Fluctuation in Capacitance Value Gentle>

Then, the mechanism that allows the gentle fluctuation in capacitive value with the aid of the shape of the capacitive element according to the second embodiment will be described with reference to the drawings.

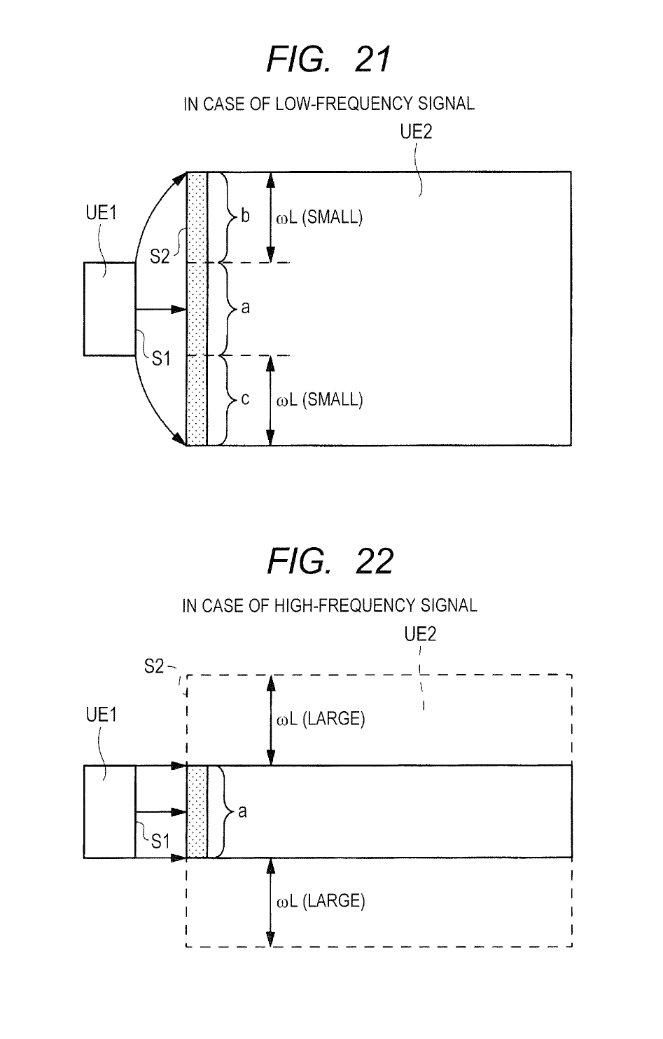

FIG. 21 is a schematic diagram illustrating one example of a part (a dotted part) of the upper electrode UE2 that functions as an effective electrode when the low frequency signal has been applied to the upper electrode UE1. In FIG. 21, the facing side S1 of the upper electrode UE1 and the facing side S2 of the upper electrode UE2 mutually face and the facing side S2 of the upper electrode UE2 includes a part a that faces the facing side S1, a part b located on the part a and a part c located under the part a. Here, when the low frequency signal has been applied to the upper electrode UE1, an electromagnetic field is generated in the upper electrode UE2 by an electromagnetic induction phenomenon, and thereby the carriers are accumulated on the part a of the facing side S2 and therefore the part a of the facing side S2 functions as an electrode. In this case, although the part b and the c each has an impedance denoted by ωL (ω=2πf, ω=angular frequency and L=parasitic inductance), when the low frequency signal has been applied, the angular frequency co is small and therefore the impedances (ωL) of the part b and the part c become small. This means that it becomes easy for the carriers to move from the part a to the part b and the part c. Consequently, as illustrated in FIG. 21, the part b and the part c function as electrodes. Accordingly, since when the low frequency signal has been applied to the upper electrode UE1, the part a, the part b and the part c of the facing side S2 of the upper electrode UE2 function as the electrodes, the capacitance value between the upper electrode UE1 and the upper electrode UE2 is increased.

On the other hand, FIG. 22 is a schematic diagram illustrating one example of the part (the dotted part) of the upper electrode UE2 that functions as the effective electrode when the high frequency signal has been applied to the upper electrode UE1. Here, when the high frequency signal has been applied to the upper electrode UE1, the electromagnetic field is generated in the upper electrode UE2 by the electromagnetic induction phenomenon, and thereby the carriers are accumulated on the part a of the facing side S2 and therefore the part a of the facing side S2 functions as the electrode. In this case, although the part b and the part c each has the impedance denoted by ωL (ω=2πf, ω=angular frequency and L=parasitic inductance), when the high frequency signal has been applied, the angular frequency co is large and therefore the impedances (ωL) of the part b and the part c become large. This means that it is difficult for the carriers to move from the part a to the part b and the part c. Consequently, as illustrated in FIG. 22, the part b and the part c do not function as the electrodes. Accordingly, since when the high frequency signal has been applied to the upper electrode UE1, only the part a of the facing side S2 of the upper electrode UE2 functions as the electrode effectively, the capacitance value between the upper electrode UE1 and the upper electrode UE2 is decreased.

From the above, according to the characteristic point (shape devising) according to the second embodiment, it is possible to impart the frequency dependency to the capacitance value between the upper electrode UE1 and the upper electrode UE2. That is, according to the capacitive element having the planar shape illustrated in FIG. 19 according to the second embodiment, it is possible to gently fluctuate the capacitance value between the upper electrode UE1 and the upper electrode UE2 with changing the signal frequency. That is, according to the capacitive element of the second embodiment, the gentle fluctuation in capacitance value between the upper electrode UE1 and the upper electrode UE2 based on shape devising in the second embodiment is added, in addition to the gentle fluctuation in capacitance value brought about by the lower electrode BE described in description of the second characteristic point of the first embodiment. Consequently, the overall capacitance value of the capacitive element according to the second embodiment fluctuates gently.

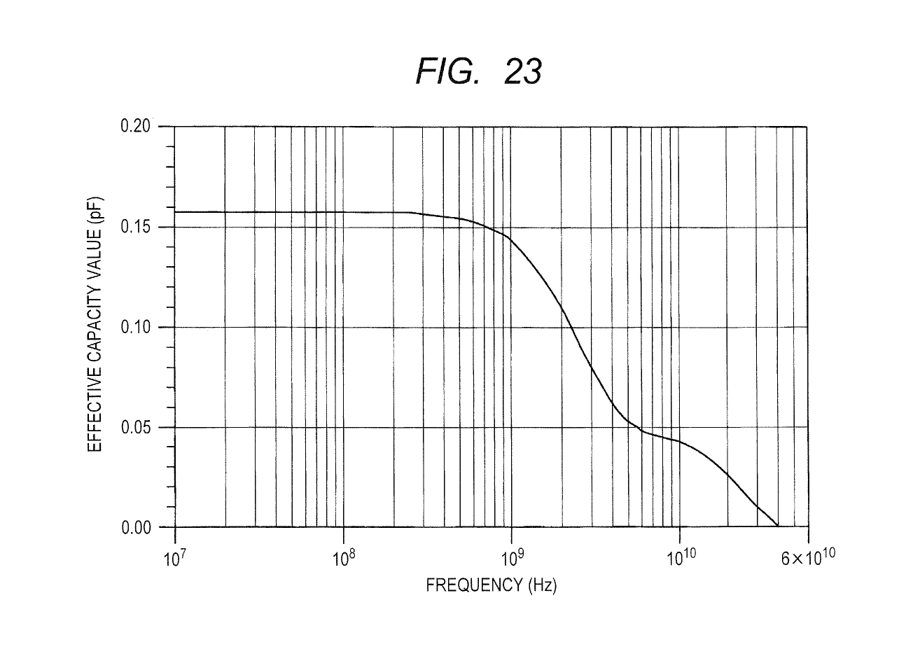

Specifically, FIG. 23 is a graph illustrating one example of a result of simulation performed on the frequency dependency of the capacitive element according to the second embodiment. In FIG. 23, the horizontal axis indicates the frequency (Hz) and the vertical axis indicates the effective capacity value (pF) of the capacitive element according to the second embodiment.

Comparing the graph in FIG. 11 with the graph in FIG. 23, it is seen that the frequency dependency that the capacitance value obtained when the high frequency signal that is higher in frequency than the low frequency signal has been applied becomes smaller than the capacitance value obtained when the low frequency signal has been applied becomes more gentle in the graph in FIG. 23 that illustrates the second embodiment than in the graph in FIG. 11 that illustrates the frequency dependency according to the first embodiment. Accordingly, since it becomes possible to make the fluctuation in capacitance value gentle according to the capacitive element of the second embodiment, it is possible to obtain such an advantage that designing of the capacitive element that copes with the digital signal is facilitated.

### Altered Example

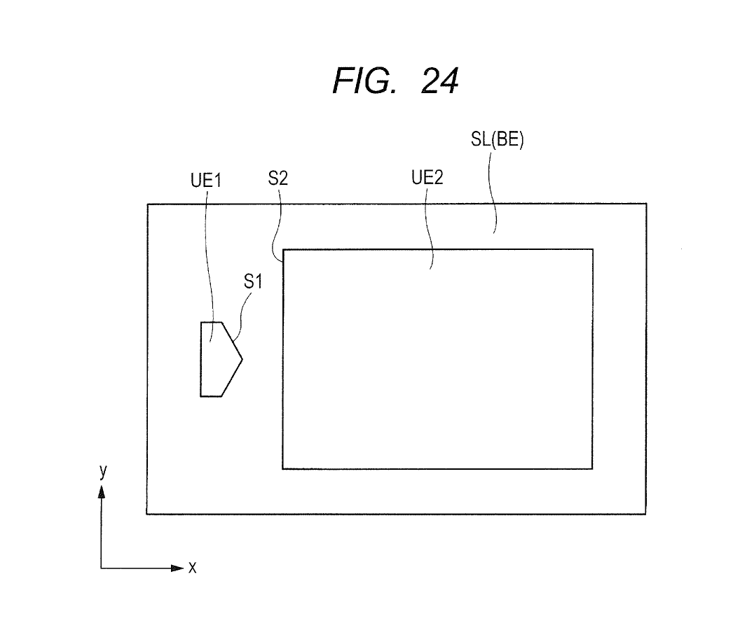

Incidentally, FIG. 24 is a schematic diagram illustrating one example of a planar layout configuration of a capacitive element according the altered example of the second embodiment. Although in the capacitive element according to the second embodiment illustrated in FIG. 19, the facing side S1 of the upper electrode UE1 and the facing side S2 of the upper electrode UE2 are formed so as to mutually face in parallel, the technical idea of the second embodiment is not limited to the above-mentioned formation of the facing sides and the facing side S1 of the upper electrode UE1 may not be formed in parallel with the facing side S2 of the upper electrode UE2, for example, as illustrated in FIG. 24. Since also in this case, it is possible to make the fluctuation in capacitance value gentle, it is possible to obtain the advantage that designing of the capacitive element that copes with the digital signal is facilitated.

### <Specific Configuration of the Capacitive Element>

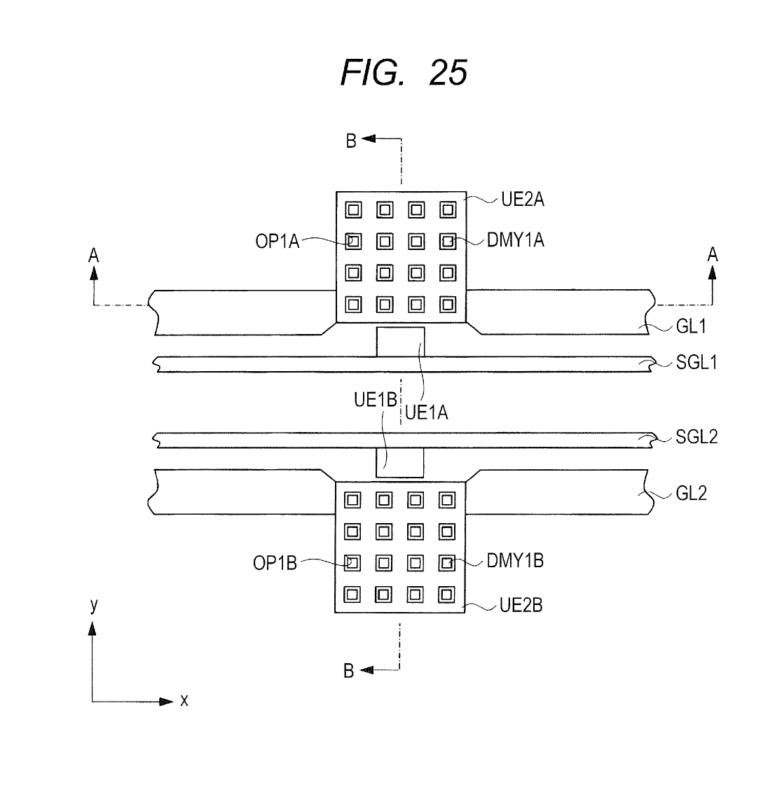

A specific configuration of the capacitive element according to the second embodiment will be described. FIG. 25 is a schematic diagram illustrating one example of a specific planar layout configuration of the capacitive element according to the second embodiment. The planar layout configuration of the capacitive element according to the second embodiment illustrated in FIG. 25 is almost the same as the planer layout configuration of the capacitive element according to the first embodiment illustrated in FIG. 14. In FIG. 25, as the point that is different from the point in FIG. 14, in the capacitive element according to the second embodiment illustrated in FIG. 25, a width in the x direction of the upper electrode UE1A (UE1B) is made narrower than a width in the x direction of the upper electrode UE2A (UE2B). That is, shape devising of the capacitive element according to the second embodiment is adopted in the planar layout configuration illustrated in FIG. 25. Thereby, since according to the capacitive element of the second embodiment, it is possible to make the fluctuation in capacitance value gentle, it is possible to obtain the advantage that designing of the capacitive element that copes with the digital signal is facilitated. In particular, not only shape devising of the capacitive element described in the second embodiment, but also the fifth characteristic point described in the first embodiment are adopted in the specific configuration of the capacitive element according to the second embodiment illustrated in FIG. 25. Accordingly, it is possible to make the fluctuation in capacitance value more gentle owing to the synergistic effect between shape devising of the capacitive element described in the second embodiment and the fifth characteristic point described in the first embodiment. Therefore, according to the specific planar layout configuration of the capacitive element illustrated in FIG. 25, it is possible to increase the advantage that designing of the capacitive element that copes with the digital signal is facilitated.

### Third Embodiment

For example, in the first embodiment, the capacitive element is arranged between the ground line GL1 and the signal line SGL1 as illustrated in FIG. 14. Although this configuration is effective when there is an allowance in wiring density, when the wiring density is increased, there is a possibility that it may become difficult to increase the wiring density by being obstructed by the upper electrode UE1A that protrudes from a middle part of the signal line SGL1.

Accordingly, in the third embodiment, devising is performed such that the capacitive element is arranged in an area that there is extra space. In the following, the technical idea in the third embodiment so devised will be described with reference to the drawing.

### <Configuration of the Semiconductor Device>

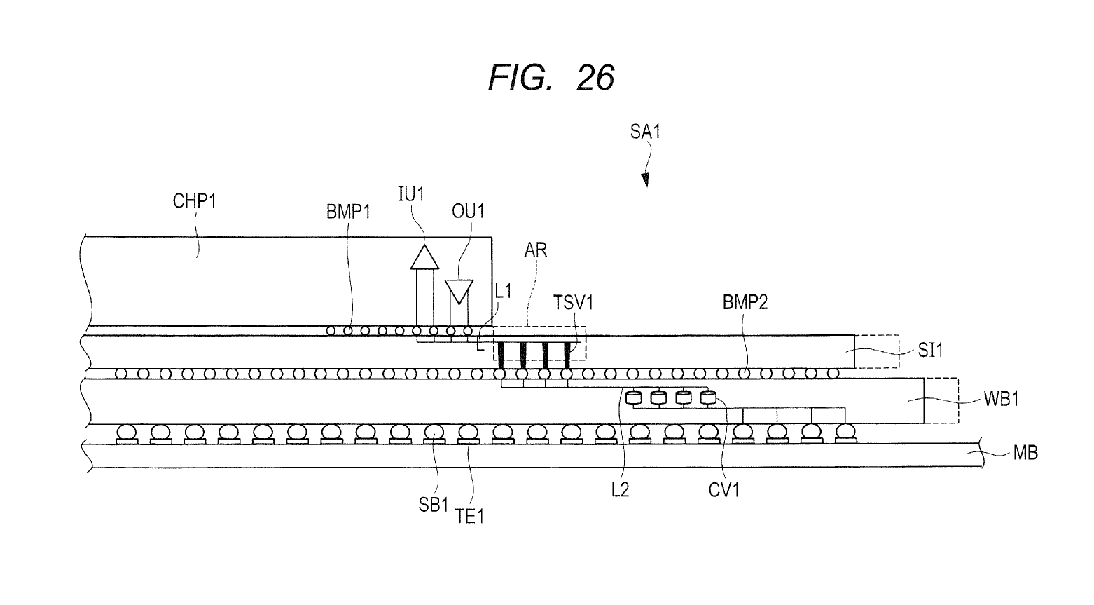

FIG. 26 is a diagram illustrating one example of a schematic configuration of the semiconductor device SA1 according to the third embodiment. Since the configuration of the semiconductor device SA1 according to the third embodiment illustrated in FIG. 26 is almost the same as the configuration of the semiconductor device SA1 according to the first embodiment illustrated in FIG. 13, description will be made centering on different points. In the semiconductor device SA1 according to the first embodiment illustrated in FIG. 13, the capacitive element according to the first embodiment is arranged in the area AR1 between the wiring line L1 and the through-via TSV1. On the other hand, in the semiconductor device SA1 according to the third embodiment, the capacitive element according to the third embodiment is arranged in the area AR that is located above the through-via TSV1 as illustrated in FIG. 26. Thereby, first, as apparent from comparison between FIG. 13 and FIG. 26, it is possible to arrange the through-via SVT1 closer to the semiconductor chip CHP1 and, as a result, it is possible to reduce the size of the silicon interposer SI1. Further, since it is also possible to shorten the wiring line L2 of the wiring board WB1, it is also possible to reduce the size of the wiring board WB1. Therefore, according to the third embodiment, it is possible to promote miniaturization of the semiconductor device SA1 owing to the synergistic effect between a reduction in size of the silicon interposer SI1 and a reduction in size of the wiring board WB1.

### <Planar Layout Configuration of the Capacitive Element>

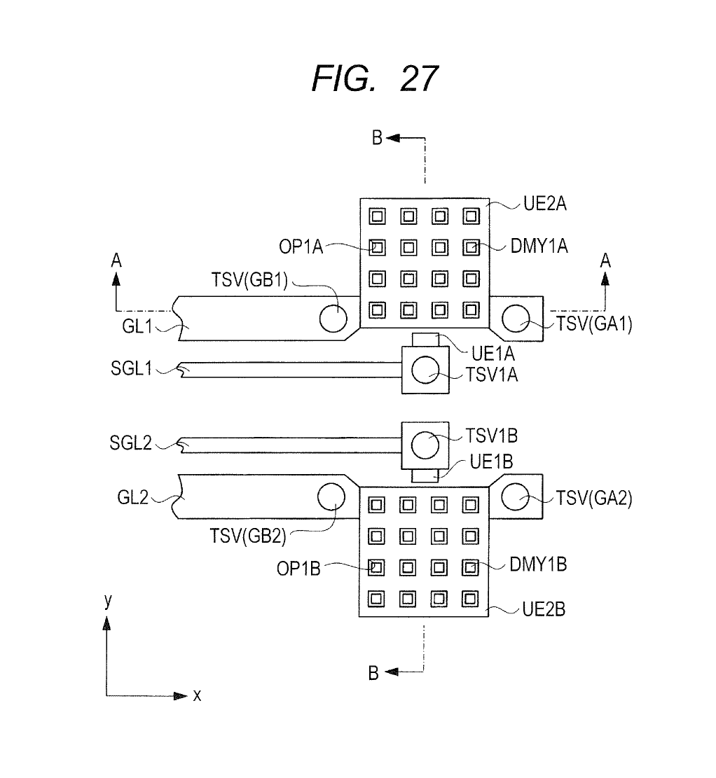

Next, one example of a planar layout configuration of the capacitive element that is formed in the area AR illustrated in FIG. 26 will be described. FIG. 27 is a plan view illustrating one example of the planar layout configuration of one pair of the capacitive elements according to the third embodiment. In FIG. 27, the signal line SGL1 extends in the x direction, and a through-via TSV1A is arranged on a termination part of the signal line SGL1. Then, in the third embodiment, the upper electrode UE1A is formed so as to be coupled with the through-via TSV1A (including the pad). On the other hand, the ground line GL1 that extends in the x direction is arranged in parallel with the signal line SGL1 and a through-via TSV(GA1) and a through-via TSV(GB1) are arranged on the ground line GL1. Then, in the third embodiment, the upper electrode UE2A is arranged so as to be interposed between the through-via TSV(GA1) and the through-via TSV(GB1) and is arranged so as to face the upper electrode UE1A. Incidentally, since the configuration of the upper electrode UE2A is the same as that in the first embodiment, description thereof is omitted. One capacitive element according to the third embodiment is formed in the above-mentioned manner.

Then, one example of the planer layout configuration of the other capacitive element according to the third embodiment will be described. In FIG. 27, the signal line SGL2 extends in the x direction and a through-via TSV1B is arranged on a termination part of the signal line SGL2. Then, in the third embodiment, the upper electrode UE1B is formed so as to be coupled with the through-via TSV1B (including the pad). On the other hand, the ground line GL2 that extends in the x direction is arranged in parallel with the signal line SGL2 and a through-via TSV(GA2) and a through-via TSV(GB2) are arranged on the ground line GL2. Then, in the third embodiment, the upper electrode UE2B is arranged so as to be interposed between the through-via TSV(GA2) and the through-via TSV(GB2) and is arranged so as to face the upper electrode UE1B. Incidentally, since the configuration of the upper electrode UE2B is the same as that in the first embodiment, description thereof is omitted. The other capacitive element according to the third embodiment is formed in the above-mentioned manner.

### <Sectional Configuration of the Capacitive Element>

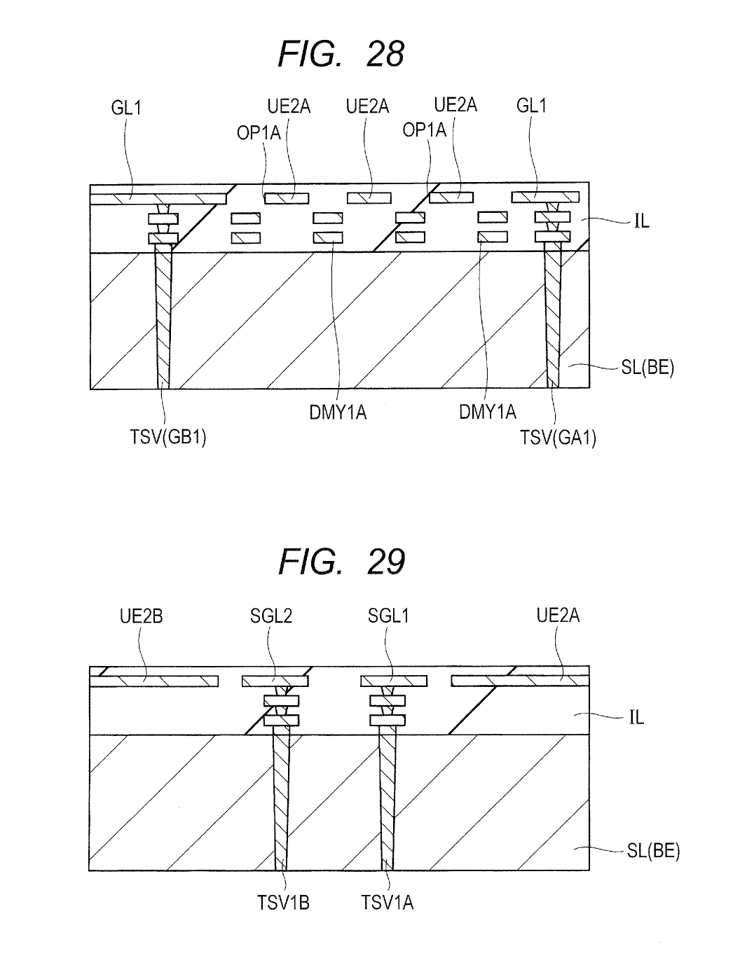

Next, one example of the sectional configuration of the capacitive element according to the third embodiment will be described. FIG. 28 is a sectional diagram taken along the A-A line in FIG. 27. As illustrated in FIG. 28, the through-via TSV(GA1) and the through-via TSV(GB1) are formed in the semiconductor layer SL that functions as the lower electrode BE so as to pass through the semiconductor layer SL. Then, the plurality of wiring layers are formed on the semiconductor layer SL via the insulating layer IL. The ground line GL1 and the upper electrode UE2A are formed by the wiring lines in the uppermost wiring layer in the plurality of wiring layers and the dummy patterns DMY1A that do not function as the wiring lines are formed in the wiring layer located lower than the uppermost wiring layer so as to be encapsulated into the openings OP1A that are installed in the upper electrode UE2. In addition, the ground line GL1 is electrically coupled with the through-via TSV(GA1) and the through-via TSV(GB1) via the wiring lines formed in the lower wiring layers.

Then, FIG. 29 is a sectional diagram taken along the B-B line in FIG. 27. As illustrated in FIG. 29, the through-via TSV1A and the through-via TSV1B are formed in the semiconductor layer SL so as to pass through the semiconductor layer SL. The through-via TSV1A is electrically coupled with the signal line SGL1 that is formed in the uppermost wiring layer in the plurality of wiring layers and the through-via TSV1B is electrically coupled with the signal line SGL2 that is formed in the uppermost wiring layer in the plurality of wiring layers.

### <Characteristic Point of Third Embodiment>

Next, the characteristic point of the third embodiment will be described. The characteristic point of the third embodiment lies in the point that, for example, as illustrated in FIG. 27, the capacitive element is arranged so as to be directly coupled with the through-via (TSV1A, TSV1B) (including the pad). For example, when the capacitive element is arranged on a middle part of the signal line, it interrupts high density arrangement of the signal lines. Accordingly, in the third embodiment, the capacitive element is arranged so as to be directly coupled with the through-via (TSV1A, TSV1B). This is because while a shielded transmission line structure is adopted for the signal line in order to suppress superimposition of the noise on the signal that is transmitted through the signal line, the shielded transmission line structure is not adopted for the through-via. That is, since the shielded transmission line structure is not adopted for the through-via, it is difficult to arrange the through-vias highly densely like the signal lines having the shielded transmission line structure in order to reduce the influence of cross coupling. In other words, it is requested to ensure a space around each through-via in order to prevent inter-signal interference (cross coupling). Therefore, in the third embodiment, focusing on this point, the space is effectively utilized by arranging the capacitive element in the space around the through-via. Consequently, according to the third embodiment, it is possible to arrange the capacitive element according to the third embodiment without interrupting the high-density arrangement of the signal lines. Further, since also the through-via itself has a parasitic capacitance, it is possible to miniaturize the capacitive element according to the third embodiment by effectively utilizing also the parasitic capacitance of the through-via. According to the technical idea of the third embodiment, it is possible to obtain a noticeable advantageous effect that it is possible to promote miniaturization of the capacitive element while coping with the high-density arrangement of the signal lines in this way.

### Altered Example

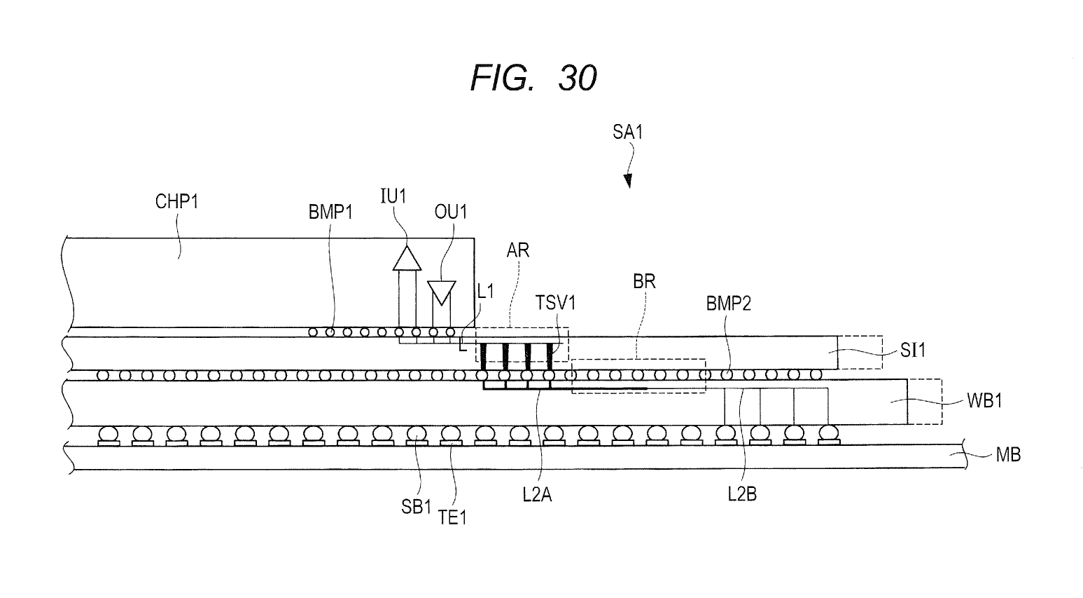

FIG. 30 is a diagram illustrating one example of a schematic configuration of the semiconductor device SA1 according to an altered example of the third embodiment. As illustrated in FIG. 30, in the altered example, the capacitive element is formed in the area AR located above the through-via TSV1 that is formed in the silicon interposer SI1 similarly to the third embodiment. Further, in the altered example, the wiring line L2A and the wiring line L2B that are mutually different in width are coupled together in an area BR instead of forming the capacitor via (the capacitor via CV1 in FIG. 26) in the wiring board WB1. That is, in the altered example, an impedance discontinuity area is formed in the area BR. In the altered example, a wiring line (L2A, L2B) formed with the impedance discontinuity area is formed in the wiring board WB1 in this way and the impedance discontinuity area is formed as an area that the width of the wiring line (L2A, L2B) changes discontinuously.

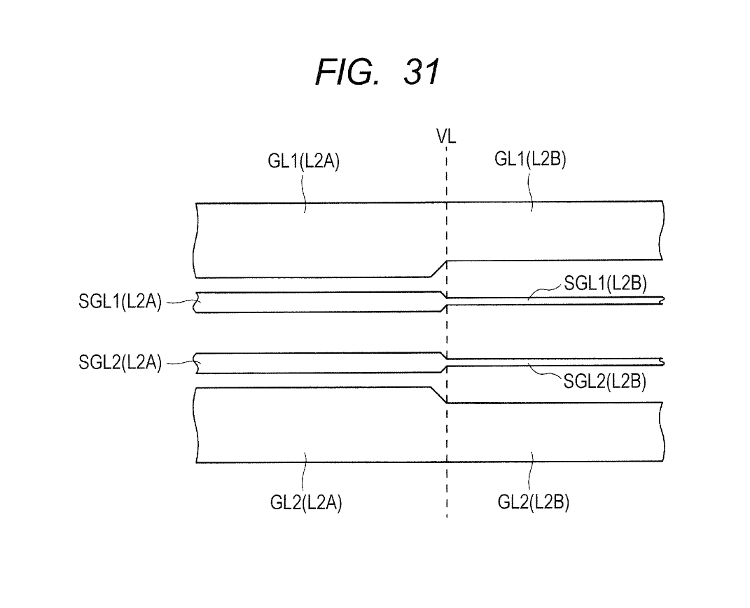

FIG. 31 is an enlarged diagram illustrating one example of a planar layout configuration of the impedance discontinuity area formed in the area BR. In FIG. 31, first, in the ground line (GL1, GL2), the right-side width is made discontinuously smaller than the left-side width with a boundary line VL being defined as a boundary. Likewise, also in the signal line (SGL1, SGL2), the right-side width is made discontinuously smaller than the left-side width with the boundary line VL being defined as the boundary. Thereby, the impedance discontinuity area that the impedance on the left side of the boundary line VL becomes discontinuously smaller than the impedance on the right side of the boundary line VL is formed. In the impedance discontinuity area so configured, reflection of the signal occurs caused by discontinuity of the impedance.

### Advantageous Effect of Altered Example

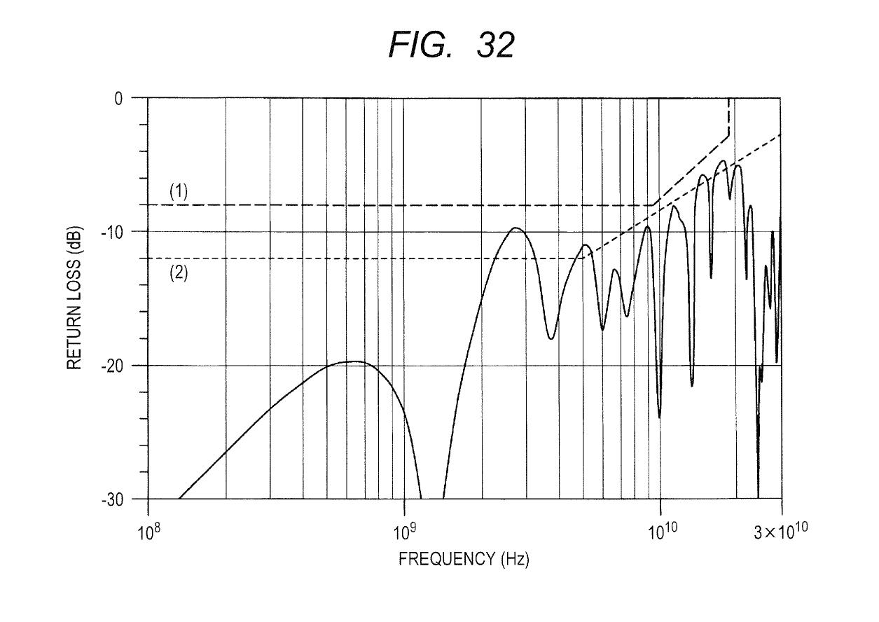

FIG. 32 is a graph illustrating one example of a relation between the frequency and a return loss (a reflection loss) in the related technology. The semiconductor device in the related technology is a semiconductor device of the type that the semiconductor chip is loaded on the wiring board without using the silicon interposer and three capacitor vias are formed in the wiring board. In the so configured semiconductor device of the related technology, as illustrated in FIG. 32, although the return loss is held within a range of a dotted line (1) that indicates a standard (a permissible range) conforming to a signal transmission speed of about 12.5 Gbps, the return loss is out of range of a dotted line (2) that indicates a standard (a permissible range) conforming to a signal transmission speed of about 30 Gbps. In particular, the return loss is beyond the permissible range in a high-frequency area. It is understood that the semiconductor device in the related technology does not fulfill the standard (the permissible range) conforming to the signal transmission speed of about 30 Gbps from the above-mentioned fact. Therefore, it is requested for the related technology to reduce the return loss in the high-frequency area.

On the other hand, in the semiconductor device SA1 according to the altered example, as illustrated in FIG. 30, the capacitive element according to the third embodiment is formed in the area AR of the silicon interposer SI1 and the impedance discontinuity area is formed in the area BR of the wiring board WB1. Thereby, according to the semiconductor device SA1 of the altered example, it is possible to reduce the return loss in the high-frequency area. This is because, firstly, in the altered example, the capacitive element according to the third embodiment is formed in the area AR of the silicon interposer SI1 and the area AR itself is located closer to the semiconductor chip CHP1 than that in the configuration illustrated, for example, in FIG. 13. This means that reflection cancellation of a signal that is higher in frequency than the signal in the example illustrated in FIG. 13 becomes possible by the capacitive element formed in the area AR and it is also possible to reduce the side effect that is called the amplification of the doubled frequency. Consequently, in the altered example, it becomes possible to reduce the return loss in the high-frequency area.

Secondly, in the altered example, the impedance discontinuity area is formed in the area AR of the wiring board WB1 instead of the capacitor via. In regard to this point, reflection of the signal in the impedance discontinuity area is more reduced than reflection of the signal in the capacitor via. However, this function of the impedance discontinuity area is imparted for the purpose of attaining reflection cancellation of the low-frequency signal and even when the effect of this reflection cancellation is reduced, the return loss in the low-frequency signal is not revealed as a matter to be solved from the beginning as apparent from FIG. 32, it is thought that no disadvantage is caused. Leaving that aside, when the capacitor via is formed, that the effect of reflection cancellation is increased means that also the side effect that is called the amplification of the doubled frequency is increased. In this case, since the doubled frequency signal is the high-frequency signal, the return loss in the high-frequency area is increased.

On the other hand, although the reflection of the signal in the impedance discontinuity area is less than the reflection of the signal in the capacitor via, this means that, viewed from the opposite side, the side effect that is called the amplification of the doubled frequency is also reduced and the impedance discontinuity area is rather more desirable than the capacitor via in order to reduce the return loss in the high-frequency area.

From the above, it is thought that according to the semiconductor device SA1 of the altered example, it is possible to reduce the return loss in the high-frequency area by forming the capacitive element according to the third embodiment in the area AR of the silicon interposer SI1 and forming the impedance discontinuity area in the area BR of the wiring board WB1.

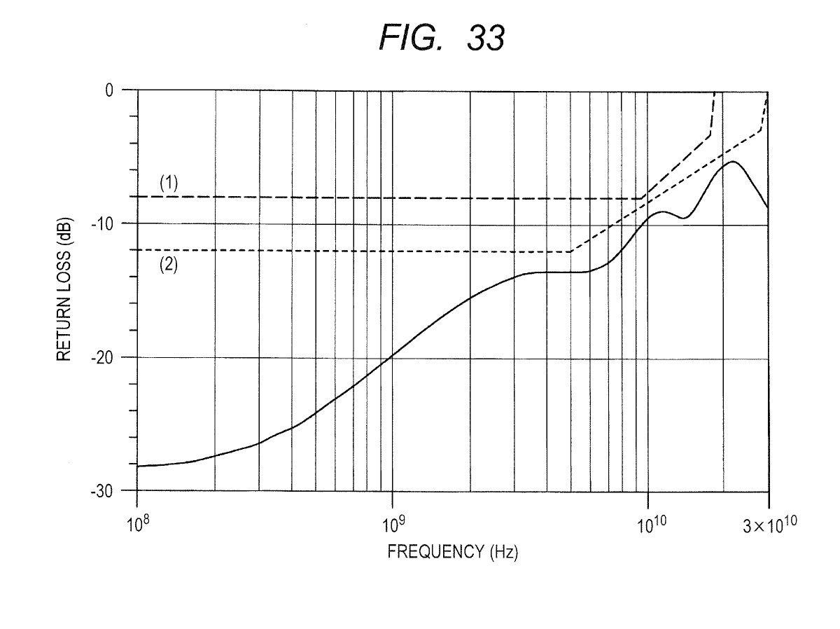

In reality, FIG. 33 is a graph illustrating one example of a relation between the frequency and the return loss (the reflection loss) in the altered example. As illustrated in FIG. 33, the return loss of the semiconductor device SA1 in the altered example is held within the range of the dotted line (1) that indicates the standard (the permissible range) confirming to the signal transmission speed of about 12.5 Gbps and is also held within the range of the dotted line (2) that indicates the standard (the permissible range) conforming to the signal transmission speed of about 30 Gbps. This means that the semiconductor device SA1 that one capacitive element that is peculiar to the altered example is used is more improved in performance of the semiconductor device than the semiconductor device of the related technology that the three capacitive elements (the capacitor vias) are used. Therefore, it is understood that the technical idea of the altered example is an excellent technical idea in the point that it is possible to promote improvement of the performance of the semiconductor device regardless of a reduction in the number of the capacitive elements.

Although, as mentioned above, the invention that has been made by the inventors and others of the present application has been specifically described on the basis of the preferred embodiments thereof, it is needless to say that the present invention is not limited to the aforementioned embodiments and may be altered and modified in a variety of ways within a range not deviating from the gist thereof.

For example, it is also possible to form the first upper electrode and the second upper electrode that configure the capacitive element in mutually different wiring layers. In this case, it is possible to make the fluctuation in capacitance value of the capacitive element having the frequency dependency more gentle.

In addition, it is also possible to impart a distribution to the impurity concentration of the conductive impurities to be introduced into the semiconductor layer in order to control the fluctuation start frequency at which the fluctuation in capacitance value is started and it is also possible to change the impurity concentration of the conductive impurities to be introduced into the semiconductor layer for every capacitive element.

What is claimed is:

1. A semiconductor device comprising:
a capacitive element that includes
a lower electrode configured by a semiconductor layer,
a first upper electrode that faces the lower electrode, and
a second upper electrode that faces the lower electrode and is arranged separately from the first upper electrode,
wherein the capacitive element has frequency dependency that a capacitance value obtained when a second frequency signal that is higher in frequency than a first frequency signal has been applied becomes smaller than a capacitance value obtained when the first frequency signal has been applied.

2. The semiconductor device according to claim 1
wherein conductive impurities are introduced into the semiconductor layer.

3. The semiconductor device according to claim 1,
wherein when the first frequency signal has been applied,
the capacitance value of the capacitive element is configured by
a first capacitance value between the lower electrode and the first upper electrode,
a second capacitance value between the lower electrode and the second upper electrode, and
a third capacitance value between the first upper electrode and the second upper electrode, and
wherein when the second frequency signal has been applied,
the capacitance value of the capacitive element is configured by the third capacitance value.

4. The semiconductor device according to claim 1,
wherein the lower electrode is formed in a semiconductor layer,
wherein the first upper electrode is formed in a first wiring layer that is formed over the semiconductor layer, and
wherein the second upper electrode is formed in the first wiring layer.

5. The semiconductor device according to claim 4,
wherein a plurality of wiring layers are formed over the semiconductor layer, and
wherein the first wiring layer is a lowermost layer in the wiring layers.

6. The semiconductor device according to claim 4,
wherein a plurality of wiring layers are formed over the semiconductor layer, and
wherein the first wiring layer is an intermediate layer in the wiring layers.

7. The semiconductor device according to claim 4,
wherein a plurality of wiring layers are formed over the semiconductor layer, and
wherein the first wiring layer is an uppermost layer in the wiring layers.

8. The semiconductor device according to claim 1,
wherein in planar view,
the first upper electrode has a first facing side that faces the second upper electrode and
the second upper electrode has a second facing side that faces the first upper electrode, and
wherein a length of the first facing side is different from a length of the second facing side.

9. The semiconductor device according to claim 8,
wherein the length of the first facing side is shorter than the length of the second facing side.

10. The semiconductor device according to claim 4,
wherein in the first wiring layer
a first wiring line that extends in a first direction and
a second wiring line that extends in the first direction and is separated from the first wiring line
are formed,
wherein the first upper electrode is coupled with the first wiring line, and
wherein the second upper electrode is coupled with the second wiring line.

11. The semiconductor device according to claim 10
wherein the first wiring line is a signal line, and
wherein the second wiring line is a ground line.

12. The semiconductor device according to claim 11,
wherein a plane area of the first upper electrode is smaller than a plane area of the second upper electrode.

13. The semiconductor device according to claim 12,
wherein a plurality of openings are formed in the second upper electrode.

14. The semiconductor device according to claim 4,
wherein in the first wiring layer
a first wiring line that extends in a first direction,
a second wiring line that extends in the first direction and is separated from the first wiring line, and
a through-via that is coupled with an end of the first wiring line are formed,
wherein the first upper electrode is coupled with the through-via, and
wherein the second upper electrode is coupled with the second wiring line.

15. A semiconductor device comprising:
a wiring board;
a relay member that is loaded over the wiring board and that a capacitive element is formed; and
a semiconductor chip that is loaded over the relay member and that an input unit and an output unit are formed,
wherein the capacitive element
includes
a lower electrode configured by a semiconductor layer,
a first upper electrode that faces the lower electrode, and
a second upper electrode that faces the lower electrode and is arranged separately from the first upper electrode, and
wherein the capacitive element
has frequency dependency that a capacitance value obtained when a second frequency signal that is higher in frequency than a first frequency signal has been applied becomes smaller than a capacitance value obtained when the first frequency signal has been applied.

16. The semiconductor device according to claim 15,
wherein when a wavelength of the first frequency signal is designated by λ,
the capacitive element is arranged at a position that is separated from the input unit or the output unit by λ/4.

17. The semiconductor device according to claim 15,
wherein the wiring board includes a wiring line that an impedance discontinuity area is formed.

18. The semiconductor device according to claim 17,
wherein the impedance discontinuity area is an area that a width of the wiring line discontinuously changes.
